(19) United States
(12) Patent Application Publication
(10) Pub. No.: US 2019/0393446 A1
(43) Pub. Date: Dec. 26, 2019

(54) GAS BARRIER FILM AND FILM FORMING METHOD

(71) Applicant: FUJIFILM Corporation, Tokyo (JP)

(72) Inventors: Yoshihiko MOCHIZUKI, Ashigarakami-gun (JP); Tatsuya INABA, Ashigarakami-gun (JP)

(73) Assignee: FUJIFILM Corporation, Tokyo (JP)

(21) Appl. No.: 16/562,323

(22) Filed: Sep. 5, 2019

Related U.S. Application Data
(63) Continuation of application No. PCT/JP2018/009900, filed on Mar. 14, 2018.

(30) Foreign Application Priority Data
Mar. 31, 2017 (JP) 2017-070148

(51) Int. Cl. H01L 51/52; C23C 16/50; C23C 16/46; C23C 16/34; C23C 16/40; C23C 16/455; H01L 31/0203; H01L 51/44; H01L 51/56

(52) U.S. Cl. CPC H01L 51/5253; C23C 16/50; C23C 16/463; C23C 16/345; H01L 2251/558; C23C 16/45525; H01L 31/0203; H01L 51/448; H01L 51/56; C23C 16/401

(57) ABSTRACT

A gas barrier film includes a support, and an inorganic layer containing at least one of oxygen, nitrogen, or carbon, silicon, and hydrogen, in which a hydrogen atom concentration in a region X of the inorganic layer is 10% to 45% by atom, a hydrogen atom concentration in a region Y is 5% to 35% by atom and is lower than the hydrogen atom concentration in the region X, and in the support, an intensity ratio of 3000 to 3500 cm⁻¹/2700 to 3000 cm⁻¹ of an IR spectrum is 1 to 7 as a ratio of inorganic layer side surface/opposite side surface. A film forming method includes heating a base material, forming an inorganic layer by hydrogen addition, and forming another inorganic layer on the base material on which the inorganic layer is formed.

### CROSS-REFERENCE TO RELATED APPLICATIONS

This application is a Continuation of PCT International Application No. PCT/JP2018/009900 filed on Mar. 14, 2018, which claims priority under 35 U.S.C § 119(a) to Japanese Patent Application No. 2017-070148 filed on Mar. 31, 2017. Each of the above application(s) is hereby expressly incorporated by reference, in its entirety, into the present application.

### BACKGROUND OF THE INVENTION

### 1. Field of the Invention

The present invention relates to a gas barrier film having excellent gas barrier properties and transparency, and a film forming method for manufacturing the gas barrier film.

### 2. Description of the Related Art

There are many products in which a material weak to oxygen or water is protected by using a gas barrier film. For example, in an organic electro luminescence (EL), flexibility is obtained by replacing a conventionally used glass substrate with a gas barrier film. The added value of a product is improved by using a gas barrier film having flexibility as a substituent for a glass substrate. Therefore, it is expected to realize a gas barrier film having flexibility and high gas barrier properties.

In recent years, in the research of the energy field, the research on solar cells has been actively conducted from the viewpoint of environmental protection and the like. Specifically, research on Cu—In—Ga—Se (CIGS)-based solar cells, organic thin film solar cells, and the like has been frequently performed.

A gas barrier film is also used in such industrial products. For example, flexibility is imparted by replacing a glass portion of a solar cell module (solar panel) with a gas barrier film, and thus flexibility and weight reduction can be achieved. Further, a gas barrier film can be applied to building materials. A gas barrier film has a wide use range and a number of activities are desired.

Such a gas barrier film is required to have high gas barrier properties such that, for example, the water vapor transmission rate is about 1×10⁻³ to 1×10⁻⁴ g/(m²·day). As a gas barrier film having high gas barrier properties, an organic-inorganic laminate type gas barrier film is known. The organic-inorganic laminate type gas barrier film is a gas barrier film having one or more combinations of an inorganic layer mainly exhibiting gas barrier properties and an organic layer to be an underlayer (undercoat layer) of the inorganic layer.

In addition, as described above, in the organic-inorganic laminate type gas barrier film, the inorganic layer mainly exhibits gas barrier properties. Therefore, it has also been proposed to obtain high gas barrier properties and the like by adjusting the hydrogen content in the inorganic layer. For example, JP2009-090634A discloses a gas barrier film having high bending resistance as well as high gas barrier properties by providing a silicon nitride layer and a hydrogenated silicon nitride layer as inorganic layers on an organic layer.

In addition, JP2014-201033A discloses a gas barrier film (film having gas barrier properties) having a barrier layer formed by depositing a deposition film containing silicon and nitrogen on an organic layer (underlayer) and then irradiating the surface of the deposition film with light having a wavelength of 150 nm or less. In this gas barrier film, the deposition film becomes denser by effectively removing a hydrogen atom derived from the Si—H bond or N—H bond included in the deposition film out of the film by irradiating the surface of the deposition film with light having a wavelength of 150 nm or less, and thus high gas barrier properties are obtained.

### SUMMARY OF THE INVENTION

In the organic EL using a gas barrier film, the light emitted from an organic EL element and transmitted through the gas barrier film is viewed. In addition, in the solar cell using a gas barrier film, the light transmitted through the gas barrier film is incident on the solar cell to generate power.

Therefore, the gas barrier film used in the organic EL or solar cell is required to have high transparency (light transmittance) as well as high gas barrier properties.

For the support of the gas barrier film, a resin film such as a polyethylene terephthalate film is used. However, according to studies conducted by the present inventors, in such a gas barrier film with a controlled hydrogen content in the inorganic layer, a resin film which is a support may be altered and decolored and thus a gas barrier film having sufficient transparency may not be obtained.

In addition, in recent years, the gas barrier properties required for the gas barrier film become increasingly more severe and it is desired to realize a gas barrier film having more excellent gas barrier properties.

The present invention is to solve the problems in the related art and an object thereof is to provide a gas barrier film having an inorganic layer like an organic-inorganic laminate type gas barrier film, and having excellent gas barrier properties and transparency, and a film forming method for manufacturing the gas barrier film.

In order to achieve the object, according to the present invention, there is provided a gas barrier film comprising: a support; and an inorganic layer which is formed on one surface side of the support and contains at least one of oxygen, nitrogen, or carbon, silicon, and hydrogen, in which in the support, a peak intensity ratio A of an infrared absorption spectrum at a surface on which the inorganic layer is formed and a peak intensity ratio B of an infrared absorption spectrum at a surface opposite to the surface on which the inorganic layer is formed satisfy 1≤peak intensity ratio A/peak intensity ratio B≤7, the peak intensity ratio A and the peak intensity ratio B are expressed as a peak intensity of 3000 to 3500 cm⁻¹/a peak intensity of 2700 to 3000 cm⁻¹, and the inorganic layer includes two regions of a region Y and a region X having the same thickness as that of the region Y and arranged to be closer to the support than the region Y, a hydrogen atom concentration L in a half (region X) on a support side in a thickness direction is 10% to 45% by atom in an atomic concentration of “[hydrogen/(silicon+hydrogen+oxygen+nitrogen+carbon)]×100”, and a hydrogen atom concentration U in a half (region Y) opposite to the support in the thickness direction is 5% to 35% by atom in an atomic concentration of “[hydrogen/(silicon+hydrogen+oxygen+nitrogen+carbon)]×100”, and is lower than the hydrogen atom concentration L.

In such a gas barrier film according to the present invention, it is preferable that a ratio of the hydrogen atom concentration U of the region Y to the hydrogen atom concentration L of the region X is 0.3 to 0.8. In other words, it is preferable that in a case where the hydrogen atom concentration in the half on the support side in the thickness direction is set to the hydrogen atom concentration L, and the hydrogen atom concentration in the half opposite to the support in the thickness direction is set to the hydrogen atom concentration U, the ratio of “hydrogen atom concentration U/hydrogen atom concentration L” is 0.3 to 0.8.

Further, it is preferable that the gas barrier film further comprises an underlying organic layer which is an underlying layer of the inorganic layer, and has one or more combinations of the underlying organic layer and the inorganic layer.

According to the present invention, there is provided a film forming method for, while transporting a long base material in a longitudinal direction, forming inorganic layers containing at least one of oxygen, nitrogen, or carbon, silicon, and hydrogen, on a surface of the base material under conditions different from each other by at least two film forming units including a first plasma CVD unit, and a second plasma CVD unit disposed on a downstream side of the first plasma CVD unit in a transport direction, the method comprising sequentially performing the steps of: heating the base material; forming the inorganic layer on the base material by the first plasma CVD unit using hydrogen as a raw material gas; and forming another inorganic layer on the base material on which the inorganic layer is formed by the second plasma CVD unit.

There is provided a film forming method in which in a case of, while transporting a long film forming material (base material) in the longitudinal direction, forming an inorganic layer containing at least one of oxygen, nitrogen, or carbon, silicon, and hydrogen on the surface of the base material by plasma CVD, a plurality of film forming units for forming an inorganic layer by plasma CVD are provided in the transport direction of the base material, and inorganic layers are formed by at least two film forming units, and a heat treatment of the base material, a treatment of forming the inorganic layer on the base material by a first plasma CVD unit using hydrogen as a raw material gas, and a treatment of forming the inorganic layer on the base material on which the inorganic layer is formed by a second plasma CVD unit are performed.

In a preferable film forming method, the inorganic layers are formed under film formation conditions different from each other so that a hydrogen atom concentration of the inorganic layer formed by a film forming unit on a downstream side in the transport direction (hereinafter, also simply referred to as “downstream side”) out of the at least two film forming units is lower than a hydrogen atom concentration of an inorganic layer formed by a film forming unit on an upstream side in the transport direction (hereinafter, also simply referred to as “upstream side”).

In a preferable film forming method, the film formation conditions are different from each other in at least one of plasma excitation power, film formation pressure, a frequency of plasma excitation power, an amount of hydrogen to be supplied as a raw material gas, or temperature of the base material.

In a more preferable film forming method, the film formation condition includes at least one selected from conditions that the plasma excitation power is higher in the film forming unit on the downstream side than in the film forming unit on the upstream side, the film formation pressure is lower in the film forming unit on the downstream side than in the film forming unit on the upstream side, the frequency of plasma excitation power is higher in the film forming unit on the downstream side than in the film forming unit on the upstream side, the amount of hydrogen to be supplied as a raw material gas is smaller in the film forming unit on the downstream side than in the film forming unit on the upstream side, and the temperature of the base material is lower in the film forming unit on the downstream side than in the film forming unit on the upstream side.

Further, it is preferable to form the inorganic layer while cooling the base material.

According to the present invention, it is possible to realize a gas barrier film having high gas barrier properties and high transparency, and a film forming method for manufacturing the gas barrier film.

### BRIEF DESCRIPTION OF THE DRAWINGS

FIG. 1 shows a first embodiment of a gas barrier film.

FIG. 2 shows a second embodiment of the gas barrier film.

FIG. 3 is a partially enlarged view of the gas barrier film shown in FIG. 1.

FIG. 4 is a view showing an embodiment of an organic film forming apparatus.

FIG. 5 is a view showing an embodiment of an inorganic film forming apparatus.

### DESCRIPTION OF THE PREFERRED EMBODIMENTS

Hereinafter, a gas barrier film and a film forming method according to embodiments of the present invention will be described in detail.

An embodiment of the gas barrier film will be described based on the drawings.

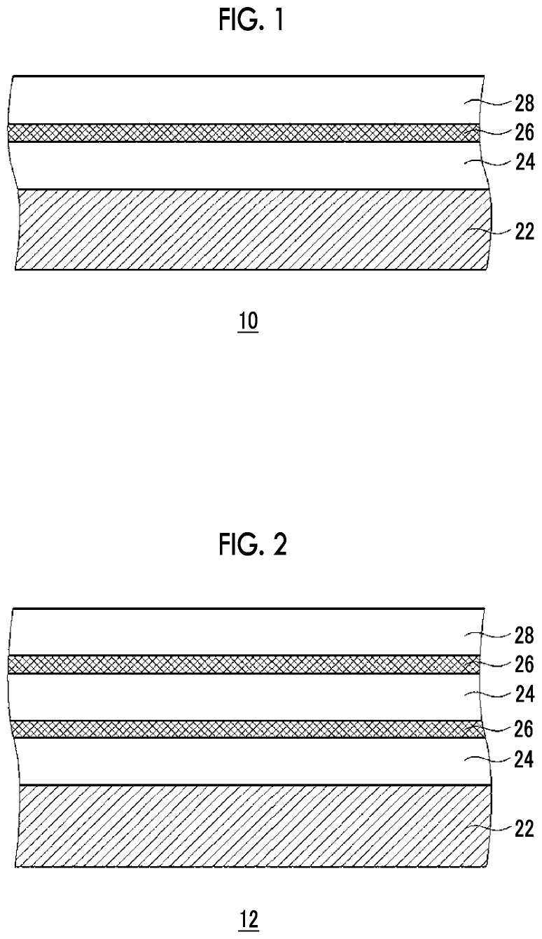

FIG. 1 shows a gas barrier film 10 which is a first embodiment. The gas barrier film 10 has a support 22, a first organic layer 24, an inorganic layer 26, and a second organic layer 28 provided on one surface of the support 22 (upper surface in FIG. 1).

FIG. 2 shows a gas barrier film 12 which is a second embodiment. The gas barrier film 12 has a support 22, a first organic layer 24 and an inorganic layer 26 provided on one surface of the support 22 (upper surface in FIG. 2), and further has a first organic layer 24, an inorganic layer 26, and a second organic layer 28 thereon.

The gas barrier films according to the embodiments of the present invention are not limited to these configurations and may be appropriately changed the layer structure. For example, the gas barrier film may have three or more combinations of the first organic layer 24 and the inorganic layer 26, and the second organic layer 28 provided on the combinations. Hereinafter, the details of each configuration will be described based on the gas barrier film 10 which is the first embodiment.

(Support 22)

As the support 22, a known sheet-like material that is used as a support in various gas barrier films and various lamination type functional films.

As the support 22, specifically, a resin film is preferably used. The material of the resin film is not particularly limited as long as the gas barrier film 10 is self-supportable.

Examples of the resin film include films of polyethylene (PE), polyethylene naphthalate (PEN), polyamide (PA), polyethylene terephthalate (PET), polyvinyl chloride (PVC), polyvinyl alcohol (PVA), polyacrylonitrile (PAN), polyimide (PI), transparent polyimide, methyl polymethacrylate resin (PMMA), polycarbonate (PC), polyacrylate, polymethacrylate, polypropylene (PP), polystyrene (PS), acrylonitrile-butadiene-styrene copolymer (ABS), a cyclic olefin copolymer (COC), a cycloolefin polymer (COP), and triacetyl cellulose (TAC).

The thickness of the support 22 may be appropriately set, depending on applications, forming materials, or the like. From the viewpoint that the mechanical strength of the gas barrier film 10 is sufficiently secured, and further, the gas barrier film 10 can be lighter and thinner, and flexibility is imparted to the gas barrier film 10, the thickness of the support 22 is preferably 5 to 150 μm and more preferably 10 to 100 μm.

The support 22 may have a functional layer on the surface thereof. For example, the functional layer may be a protective layer, an adhesive layer, a light reflecting layer, an antireflection layer, a light shielding layer, a flattening layer, a buffer layer, or a stress relaxation layer.

Here, in the present invention, on the surface on which the inorganic layer 26 is formed and the surface opposite to the surface on which the inorganic layer 26 is formed in the support 22, the characteristics of the peak intensity ratios of infrared absorption spectra are different. In the following description, the surface of the support 22 on which the inorganic layer 26 is formed is referred to as “front surface” of the support 22 and the surface opposite to the surface on which the inorganic layer 26 is formed is referred to as “rear surface” of the support 22.

Specifically, in the gas barrier film 10 according to the embodiment of the present invention, in the case where a ratio “peak intensity of 3000 to 3500 cm⁻¹/peak intensity of 2700 to 3000 cm⁻¹” in the infrared absorption spectrum in the front surface of the support 22 is a peak intensity ratio A, and a ratio “peak intensity of 3000 to 3500 cm⁻¹/peak intensity of 2700 to 3000 cm⁻¹” in the rear surface of the support 22 is a peak intensity ratio B, “1≤peak intensity ratio A/peak intensity ratio B≤7” is satisfied.

In the gas barrier film 10 according to the embodiment of the present invention, since the peak intensity ratios of the infrared absorption spectra of the front surface and the rear surface of the support 22 have such characteristics, the support 22 is prevented from being altered (deteriorated) and causing coloration such as yellowing to deteriorate transparency. Thus, a highly transparent gas barrier film is realized.

In the infrared absorption spectrum, the peak of 3000 to 3500 cm⁻¹ is derived from the stretching vibration of O—H bonds. In addition, the peak of 2700 to 3000 cm⁻¹ is derived from the stretching vibration of C—H bonds.

As will be described later, in the gas barrier film 10 according to the embodiment of the present invention, the inorganic layer 26 is formed by, for example, plasma CVD. In the film formation by plasma CVD, in the case where the gas decomposed or excited in the plasma returns to the ground state, an ultraviolet ray with a short wavelength called a vacuum ultraviolet ray is generated. In addition, in the gas barrier film 10 according to the embodiment of the present invention, in a half opposite to the support 22 in the thickness direction of the inorganic layer 26, the decomposition of the raw material gas is promoted to form an inorganic layer with a low hydrogen content. In the state where the decomposition of the raw material gas is promoted, the amount of vacuum ultraviolet rays generated is increased.

In the case where ultraviolet rays are incident on the support 22 which is a resin film, the chemical bonds of the component constituting the support 22, for example, part of functional groups of the main chain and the side chain of the resin is cut. As a result, the support 22 is altered to cause so-called yellowing or the like in which the support 22 is colored yellow, and the support 22 is colored. In the case where the support 22 is colored, the transparency of the support 22 is decreased, that is, the transparency of the gas barrier film 10 is decreased.

Particularly, in the configuration in which a silicon nitride layer is formed and then a hydrogenated silicon nitride layer is formed as shown in JP2009-090634A, and the configuration in which a deposition film containing silicon and nitrogen is formed and then the deposition film forming surface is irradiated with light having a wavelength of 150 nm or less as shown in JP2014-201033A, the alternation of the support 22 easily proceeds.

Here, in the case where the linear chain of the support 22 which is a resin film is cut, the cut portion is often terminated with a —OH group. That is, in the case where the number of cutting of the linear chain of the support 22 by ultraviolet rays increases, the number of C—H bonds decreases and the number of O—H bonds increases. Therefore, in the support 22 of which the linear chain is cut, the peak of 3000 to 3500 cm⁻¹ derived from the stretching vibration of the O—H bond becomes large, and the peak of 2700 to 3000 cm⁻¹ derived from the stretching vibration of the C—H bond becomes small.

Accordingly, the peak intensity ratio of “peak intensity of 3000 to 3500 cm⁻¹/peak intensity of 2700 to 3000 cm⁻¹” in the infrared absorption spectrum of the support 22 increases as the number of cutting of the linear chain by ultraviolet light increases.

In addition, the vacuum ultraviolet ray is gradually absorbed by the support 22, that is, the resin film. Therefore, the rear surface of the support 22 on the side on which the inorganic layer 26 is not formed is less altered by the vacuum ultraviolet ray than the front surface of the support 22 on the side on which the inorganic layer 26 is formed.

That is, the peak intensity ratio of “peak intensity of 3000 to 3500 cm⁻¹/peak intensity of 2700 to 3000 cm⁻¹” in the infrared absorption spectrum of the support 22 is smaller in the front surface of the support 22 than in the rear surface.

Further, it is considered that as the ratio “peak intensity ratio A/peak intensity ratio B”, which is a ratio of the peak intensity ratio A on the front surface of the support 22 to the peak intensity ratio B on the rear surface of the support 22, becomes larger, the alteration of the support 22 by the vacuum ultraviolet ray becomes larger.

In the gas barrier film 10 according to the embodiment of the present invention, the infrared absorption spectrum satisfies “1≤peak intensity ratio A/peak intensity ratio B≤7” on the front surface and the rear surface of the support 22. In the present invention, with such a configuration, the coloration caused by alteration of the support 22 due to the vacuum ultraviolet ray is suppressed, and thus the gas barrier film 10 with high transparency is realized.

As described above, the alteration caused by the vacuum ultraviolet ray is larger on the surface than the rear surface of the support 22. Therefore, the ratio “peak intensity ratio A/peak intensity ratio B” cannot be less than 1, and in the case of “peak intensity ratio A/peak intensity ratio B=1”, it is considered that there is almost no alteration in the support 22 by the vacuum ultraviolet ray.

In the case where the ratio “peak intensity ratio A/peak intensity ratio B” is more than 7, the alteration of the support 22 by the vacuum ultraviolet ray is large, and the color of the support 22 is large, so that the gas barrier film 10 having sufficient transparency cannot be obtained.

The ratio “peak intensity ratio A/peak intensity ratio B” is preferably “1≤peak intensity ratio A/peak intensity ratio B≤5” and more preferably “1≤peak intensity ratio A/peak intensity ratio B≤3”.

In the present invention, the infrared absorption spectra of the front surface and the rear surface of the support 22 can be measured by cutting the gas barrier film 10, and analyzing the front surface and the rear surface of the support 22 in the cross section of the gas barrier film 10 by micro infrared spectroscopy (micro infra red (IR)) using an attenuated total reflectance (ATR).

In the analysis of the cross section by this microscopic IR, the front surface and the rear surface of the support 22 indicate regions at 15 μm in the thickness direction of the support 22 from the interface with the surfaces adjacent to the support 22. In the case of the gas barrier film 10 of the shown example, regarding the surfaces adjacent to the support 22, the surface side is the first organic layer 24 and the rear surface side is air (gas).

(First Organic Layer 24: Underlying Organic Layer)

The first organic layer 24 is provided on the support 22.

The first organic layer 24 is formed of, for example, an organic compound formed by polymerizing a monomer or oligomer (crosslinked, hardened).

The first organic layer 24 is provided as a preferable embodiment and is an underlying organic layer in which the unevenness of the surface of the support 22 and foreign matter attached to the surface of the support 22 are embedded.

The gas barrier film 10 shown in FIG. 1 has one combination of an underlying organic layer and an inorganic layer, and the gas barrier film 12 shown in FIG. 2 has two or more combinations of an underlying organic layer and an inorganic layer.

As the number of combinations of an underlying organic layer and an inorganic layer increases, higher gas barrier properties are obtained, but the thickness of the gas barrier film is increased.

(First Organic Layer Forming Composition: Underlying Organic Layer Forming Composition)

The first organic layer 24 is formed by, for example, curing a first organic layer forming composition. For example, the first organic layer forming composition contains a thermoplastic resin and an organic compound such as an organosilicon compound. Examples of the thermoplastic resin include polyester, (meth)acrylic resin, a methacrylic acid-maleic acid copolymer, polystyrene, transparent fluorine resin, polyimide, fluorinated polyimide, polyamide, polyamide imide, polyether imide, cellulose acylate, polyurethane, polyether ether ketone, polycarbonate, alicyclic polyolefin, polyarylate, polyether sulfone, polysulfone, fluorene ring-modified polycarbonate, alicyclic modified polycarbonate, fluorene ring-modified polyester, and an acrylic compound. Examples of the organosilicon compound include polysiloxanes. The first organic layer 24 may contain one organic compound or two or more organic compounds.

The first organic layer forming composition preferably contains a polymer of a radically curable compound and/or a cationically curable compound having an ether group from the viewpoint of excellent strength of the first organic layer 24 and glass transition temperature.

The first organic layer forming composition preferably contains a (meth)acrylic resin having a polymer of a monomer or oligomer of (meth)acrylate as a main component from the viewpoint of lowering the refractive index of the first organic layer 24. By lowering the refractive index, the first organic layer 24 has high transparency and improved light transmittance.

The first organic layer forming composition more preferably contain (meth)acrylic resins having bifunctional or higher polymers of monomers or oligomers of (meth)acrylate as a main component, and particularly preferably contains, trifunctional or higher polymers of monomers or oligomers of (meth)acrylate as a main component, such as dipropylene glycol di(meth)acrylate (DPGDA), trimethylolpropane tri(meth)acrylate (TMPTA), and dipentaerythritol hexa(meth)acrylate (DPHA). In addition, a plurality of these (meth)acrylic resins may be used. The main component refers to a component having the largest content mass ratio among the contained components.

The first organic layer forming composition preferably contains an organic solvent, an organic compound (monomer, dimer, trimer, oligomer, polymer, and the like), a surfactant, a silane coupling agent, and the like.

The thickness of the first organic layer 24 can be appropriately set according to the components contained in the first organic layer forming composition and the used support 22. The thickness of the first organic layer 24 is preferably 0.5 to 5 μm and more preferably 1 to 3 μm. By setting the thickness of the first organic layer 24 to 0.5 μm or more, the unevenness of the surface of the support 22 or the foreign matter attached to the surface of the support 22 are embedded so that the surface of the first organic layer 24 can be flattened. By setting the thickness of the first organic layer 24 to 5 μm or less, it is possible to suppress the occurrence of cracks in the first organic layer 24 and curling of the gas barrier film 10.

In the case where a plurality of first organic layers 24 are provided (refer to FIG. 2), the thickness of each first organic layer 24 may be the same or different from each other.

The first organic layer 24 can be formed by a known method. Specifically, the first organic layer 24 can be formed by applying and drying the first organic layer forming composition. Further, the first organic layer 24 can be formed by polymerizing (crosslinking) the organic compound in the first organic layer forming composition by irradiation with ultraviolet rays as necessary.

The first organic layer 24 is preferably formed by a so-called roll-to-roll method. In the following description, the “roll-to-roll” is also referred to as “R-to-R”. R-to-R is a manufacturing method in which from a roll formed by winding a long film formation target sheet, the film formation target sheet is fed, film formation is performed while transporting the film formation target sheet in the longitudinal direction, and the film formed sheet is wound in a roll shape. By using R-to-R, high productivity and manufacturing efficiency can be obtained.

(Inorganic Layer 26)

The inorganic layer 26 is a thin film containing an inorganic compound, is formed on one surface side of the support 22, and is provided on the surface of the first organic layer 24. The inorganic layer 26 exhibits gas barrier properties.

The inorganic layer 26 is properly formed by being provided on the surface of the first organic layer 24. The support 22 has a region in which the inorganic compound is not easily deposited, such as unevenness of the surface and the shadow of foreign matter. By providing the first organic layer 24 on the support 22, the region in which the inorganic compound is not easily deposited is covered. Therefore, the inorganic layer 26 can be formed on the entire surface of the support 22 without a gap.

In the gas barrier film 10 of the present invention, the inorganic layer 26 is a layer having an inorganic compound containing at least one of oxygen, nitrogen and carbon, silicon and hydrogen.

Examples of such inorganic compounds include silicon nitride, silicon oxide, silicon carbide, silicon oxynitride, silicon carbonitride, silicon oxynitride carbide, and silicon oxycarbide. Moreover, these inorganic compounds inevitably contain hydrogen, regardless of which compound is used.

The thickness of the inorganic layer 26 can be suitably set according to the kind of inorganic compound so that gas barrier properties can be exhibited. The thickness of the inorganic layer 26 is preferably 10 to 200 nm, more preferably 15 to 100 nm, and particularly preferably 20 to 75 nm. By setting the thickness of the inorganic layer 26 to 10 nm or more, sufficient gas barrier performance can be stably exhibited. The inorganic layer 26 is generally brittle, and in the case where the inorganic layer is too thick, the inorganic layer may cause cracking or peeling. By setting the thickness of the inorganic layer 26 to 200 nm or less, cracking and peeling can be prevented.

In the case where the inorganic layer 26 is formed of silicon nitride, since the inorganic layer is very dense and has high density, for example, very high gas barrier properties can be obtained even at a thickness of about 30 nm. In the case where the inorganic layer 26 is formed of silicon nitride, it is possible to obtain a gas barrier film having not only excellent gas barrier properties, but also small thickness, high transparency, high flexibility, and high quality.

In the case where a plurality of inorganic layers 26 are provided (refer to FIG. 2), the thickness of each inorganic layer 26 may be the same or different from each other. In addition, each inorganic layer 26 can be formed using the same first inorganic layer forming material.

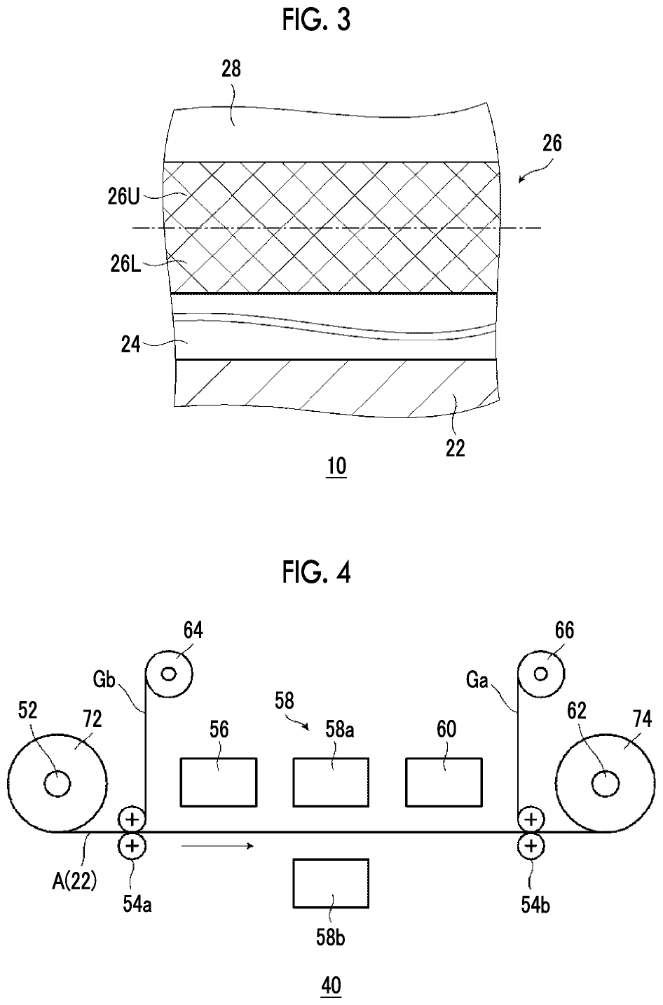

Here, in the gas barrier film 10 according to the embodiment of the present invention, the inorganic layer 26 includes a region Y on the second organic layer 28, and a region X having the same thickness as that of the region Y and arranged to be closer to the support 22 than the region Y. As shown conceptually in FIG. 3, with respect to the center in the thickness direction indicated by the dashed dotted line, the inorganic layer is formed by a half 26L (region X) on the support 22 side in the thickness direction and a half 26U (region Y) on the second organic layer 28 side in the thickness direction. A hydrogen atom concentration L in the region X is 10% to 45% by atom (at %) in an atomic concentration of “[hydrogen/(silicon+hydrogen+oxygen+nitrogen+carbon)]×100”, and a hydrogen atom concentration U in the region Y is 5% to 35% by atom in an atomic concentration of “[hydrogen/(silicon+hydrogen+oxygen+nitrogen+carbon)]×100”, and is lower than the hydrogen atom concentration L.

In the following description, the half of the inorganic layer 26 on the support 22 side is also referred to as “support side 26L” of the inorganic layer 26, and the half of the inorganic layer 26 opposite to the support 22 is also referred to as “surface side 26U” of the inorganic layer 26. In other words, the thickness direction of the inorganic layer 26 is the lamination direction of the support 22, the first organic layer 24, the inorganic layer 26, and the second organic layer 28. In the following description, the support 22 side of the gas barrier film 10 is also referred to as “down”, and the second organic layer 28 side is also referred to as “up”.

In the present invention, since the infrared absorption spectra of the front surface and the rear surface of the support 22 have the above-mentioned characteristics, and the inorganic layer 26 has such a hydrogen atom concentration (hereinafter, also simply referred to as “hydrogen concentration”), a gas barrier film having excellent gas barrier properties and transparency is realized.

In the gas barrier film having an inorganic layer, in order to obtain high gas barrier properties, it is important that the inorganic layer appropriately and entirely covers the unevenness and the like of the surface to be formed without pinholes or defects.

Here, in the case of forming an inorganic layer containing silicon, in order to form an inorganic layer without pinholes or the like, it is preferable to perform film formation in a state in which the active species obtained by decomposing the raw material gas has a large amount of hydrogen. For example, in the case of forming a film of silicon nitride using silane (SiH₄), SiH₃ in which silane is decomposed and one hydrogen is removed is more preferable than SiH in which silane is decomposed and only one hydrogen is attached to silicon.

That is, in order to form an inorganic layer without pinholes and the like, it is preferable that the hydrogen concentration in the inorganic layer to be formed is high.

Specifically, in the formation of the inorganic layer containing silicon, in a state in which the amount of hydrogen contained in the active species is small, the adhesion probability of the active species is high, and in the case of being in contact with the formation surface, the film is deposited at the contact position. That is, in the case where the amount of hydrogen contained in the active species is small, a large number of films are formed on portions that the active species easily reaches, such as convex portions of the formation surface, and it is difficult to form a flat inorganic layer without pinholes or the like.

In contrast, in a state in which the active species has a large amount of hydrogen, the adhesion rate of the active species is low. Therefore, the active species moves on the surface even in the case where the active species reaches the formation surface without being deposited on the portion of the formation surface that the active species easily reaches, and is deposited on the portion that the active species easily reaches, such as a concave portion of the formation surface. That is, by forming the inorganic layer with the active species having a large amount of hydrogen, it is possible to form a flat inorganic layer which entirely covers the formation surface without causing a defect.

On the other hand, the inorganic layer containing silicon formed by the active species having a large amount of hydrogen, that is, the inorganic layer having a high hydrogen concentration has a low density and low gas barrier properties.

Therefore, in the inorganic layer containing silicon, in order to obtain high gas barrier properties, it is advantageous to form a high density inorganic layer by active species with less hydrogen. That is, the inorganic layer containing silicon has higher gas barrier properties as the hydrogen concentration becomes lower.

The present invention has been made by obtaining the knowledge on the infrared absorption spectra of the front surface and the rear surface of the support 22 described above, and in the inorganic layer 26, the hydrogen concentration at the support side 26L is 10% to 45% by atom in an atomic concentration of “[hydrogen/(silicon+hydrogen+oxygen+nitrogen+carbon)]×100”, and the hydrogen concentration on the surface side 26U is 5% to 35% by atom in an atomic concentration of “[hydrogen/(silicon+hydrogen+oxygen+nitrogen+carbon)]×100”, and is lower than the hydrogen concentration on the support side 26L.

That is, since the inorganic layer 26 of the gas barrier film 10 according to the embodiment of the present invention has the region X (support side 26L) having a high hydrogen concentration and formed in a state of being rich in hydrogen contained in the active species on the support 22 side, the unevenness and the like of the first organic layer 24 are suitably covered to form a flat film without pinholes and the like. On this flat support side 26L, the region Y (surface side 26U) which is formed in a state in which the amount of hydrogen contained in the active species is small, and has a low hydrogen concentration, high density, and high gas barrier properties is provided. Since the support side 26L is flat without pinholes and the like, the surface side 26U formed on the support side 26L is also flat without pinholes and the like.

The gas barrier film 10 according to the embodiment of the present invention exhibits very high gas barrier properties by providing such an inorganic layer 26.

In addition, when the surface side 26U of the inorganic layer 26 formed in a state in which the amount of hydrogen contained in the active species is small, that is, the decomposition of the raw material gas is further promoted, and the amount of the above-mentioned vacuum ultraviolet rays generated is increased. That is, in the case of forming an inorganic layer having a low hydrogen concentration, the alteration of support 22 easily proceeds.

In contrast, in the gas barrier film 10 according to the embodiment of the present invention, the inorganic layer 26 has a high hydrogen concentration on the support side 26L. Therefore, in the case where the region X which is the surface side 26U of the inorganic layer 26 is formed, even in the case where a large amount of vacuum ultraviolet rays are generated by promoting the decomposition of the raw material gas, the vacuum ultraviolet rays pass through the region to be the support side 26L and reach the support 22. In the case where the vacuum ultraviolet rays are incident on the region which is the support side 26L, similar to the action described above in the support 22, hydrogen is released by breaking up the Si—H bond, the N—H bond, and the like remaining in the region Y in which the vacuum ultraviolet rays are on the support side 26L, and thus the vacuum ultraviolet rays are absorbed by the region Y which is the support side 26L.

That is, in the gas barrier film 10 according to the embodiment of the present invention, the support side 26L of the inorganic layer 26 also acts as a protective layer for protecting the support 22 (and the first organic layer 24) from the vacuum ultraviolet rays. Accordingly, in the formation of the inorganic layer 26, even in the case where the formation of the inorganic layer 26 is performed in a state in which the decomposition of the raw material gas is promoted in order to lower the hydrogen concentration on the surface side 26U, the vacuum ultraviolet rays incident on the support 22 can be significantly reduced to prevent alteration of the support 22.

In other words, there is a trade-off relationship between the prevention of alteration of the support 22 by the vacuum ultraviolet rays and the exhibition of high gas barrier properties by the surface side 26U of the inorganic layer 26. However, according to the gas barrier film 10 according to the embodiment of the present invention, there is no need to consider the alteration of the support 22 in the inorganic layer 26, and the region X to be the surface side 26U having a low hydrogen concentration, high density, and high gas barrier properties is formed so that both high transparency and high gas barrier properties can be obtained.

In the inorganic layer 26, the hydrogen concentration in the support side 26L is 10% to 45% by atom in an atomic concentration of “[hydrogen/(silicon+hydrogen+oxygen+nitrogen+carbon)]×100”.

In the case where the hydrogen concentration in the support side 26L is less than 10% by atom, an inorganic layer 26 without pinholes and the like cannot be formed, the alteration of the support 22 (first organic layer 24) cannot be sufficiently suppressed in the case where the region which is the support side 26L of the inorganic layer 26 is formed, flexibility is not provided, and problems such as cracking easily arise.

On the other hand, in the case where the hydrogen concentration in the support side 26L is more than 45% by atom, there arise problems that sufficient gas barrier properties cannot be obtained and the like.

The hydrogen concentration on the support side 26L is preferably 15% to 42% by atom and more preferably 20% to 40% by atom.

In the inorganic layer 26, the hydrogen concentration in the surface side 26U is 5% to 35% by atom in an atomic concentration of “[hydrogen/(silicon+hydrogen+oxygen+nitrogen+carbon)]×100”.

In the case where the hydrogen concentration on the surface side 26U is 5% by atom or more, the alteration of the support 22 (first organic layer 24) in the case where the region which is the surface side 26U of the inorganic layer 26 is formed can be sufficiently suppressed, flexibility is provided, and problems such as cracking do not easily arise.

In the case the hydrogen concentration on the surface side 26U is 35% by atom or less, sufficient gas barrier properties can be obtained.

The hydrogen concentration on the surface side 26 U is preferably 7% to 32% by atom and more preferably 10% to 30% by atom.

In the inorganic layer 26, in the case where the hydrogen concentration on the surface side 26U is lower than the hydrogen concentration on the support side 26L, the inorganic layer 26 without pinholes and the like can be formed, and the alteration of the support 22 (first organic layer 24) can be sufficiently suppressed in the case of forming the surface side 26U.

In the gas barrier film 10 according to the embodiment of the present invention, the hydrogen concentration on the surface side 26U of the inorganic layer 26 and the hydrogen concentration on the support side 26L can be measured using a Rutherford backscattering spectrometry/hydrogen forward scatterometry (RBS/HFS).

Specifically, the hydrogen concentration (% by atom) may be calculated by “[hydrogen/(silicon+hydrogen+oxygen+nitrogen+carbon)]×100” by detecting the amount (number) of each of atoms of silicon, hydrogen, oxygen, nitrogen, and carbon in the entire region of the inorganic layer 26 in the thickness direction by using the RBS/HFS method, dividing the detected results into the surface side 26U and the support side 26L at the center of the inorganic layer 26 in the thickness direction, and respectively counting each number of atoms in the surface side 26U and the support side 26L.

In the gas barrier film 10 according to the embodiment of the present invention, as long as the hydrogen concentration on the surface side 26U is lower than the hydrogen concentration on the support side 26L, the difference between the two hydrogen concentrations in the inorganic layer 26 is not particularly limited.

Here, in the inorganic layer 26, the ratio of the hydrogen atom concentration U of the region Y to the hydrogen atom concentration L of the region X “hydrogen concentration U/hydrogen concentration L” is preferably 0.3 to 0.8.

By setting the “hydrogen concentration U/hydrogen concentration L” to 0.3 or more, the stress difference in the thickness direction of the inorganic layer 26 is sufficiently reduced and the occurrence of damage such as cracking or cracks in the case of receiving an external force such as bending can be prevented.

By setting the “hydrogen concentration U/hydrogen concentration L” to 0.8 or less, the effect of having a difference in hydrogen concentration between the surface side 26U and the support side 26L is suitably exhibited, and both the effect of preventing deterioration of the gas barrier properties caused by the lack of film density in a region in which the amount of hydrogen is large, and the effect of preventing alteration of the support 22 by vacuum ultraviolet rays in a region in which the amount of hydrogen is small are more suitably exhibited. Thus, it is possible to more suitably obtain both the effect of preventing the alteration of the support 22 and the effect of improving the gas barrier properties.

The “hydrogen concentration U/hydrogen concentration L” is more preferably 0.35 to 0.75 and even more preferably 0.4 to 0.7.

The surface smoothness of the inorganic layer 26 is not particularly limited. However, the inorganic layer 26 preferably has high surface smoothness, preferably has a surface roughness Ra of 5 nm or less, and more preferably 3 nm or less.

The fact that the surface roughness Ra of the inorganic layer 26 is 5 nm or less means that the support side 26L has sufficient coatability and smoothness and the gas barrier film 10 exhibits higher gas barrier properties.

In the present invention, the surface roughness Ra (arithmetic mean roughness Ra) may be measured in accordance with JIS B 0601 (2001).

The gas barrier film according to the embodiment of the present invention may have a plurality of inorganic layers 26 as in the gas barrier film 12 shown in FIG. 2. That is, a plurality of combinations of an underlying organic layer and an inorganic layer may be provided.

Here, in the case where the gas barrier film according to the embodiment of the present invention has a plurality of inorganic layers 26, in the inorganic layer 26 closest to the support 22 (the lowermost inorganic layer 26), as long as the hydrogen concentrations on the support side 26L and the surface side 26U satisfy the above conditions, other inorganic layers 26 have no limitation on the hydrogen concentration.

Therefore, in the case of having a plurality of inorganic layers 26, the hydrogen concentrations of all the inorganic layers 26 may satisfy the above conditions, or the hydrogen concentration of one or more of the inorganic layers 26 excluding the inorganic layer 26 closest to the support 22 may not satisfy the above conditions. However, in the present invention, in the case of having a plurality of inorganic layers 26, it is preferable that the hydrogen concentrations of all the inorganic layers 26 satisfy the above-mentioned conditions.

As the method for forming the inorganic layer 26, various vapor phase film forming methods such as plasma CVD such as capacitively coupled plasma (CCP)-chemical vapor deposition (CVD) and inductively coupled plasma (ICP)-CVD, an atomic layer deposition (ALD) method, sputtering such as magnetron sputtering, and vacuum evaporation may be used, but preferably, the inorganic layer 26 is formed by the film forming method described below. In addition, the atomic layer deposition method is also suitably used to form the inorganic layer 26.

By forming the inorganic layer 26 by the film forming method according to the embodiment of the present invention, the gas barrier film 10 according to the embodiment of the present invention in which the hydrogen concentrations of the support side 26L of the inorganic layer 26 and the hydrogen concentration of the surface side 26U satisfy the above conditions, and the peak intensity of the infrared absorption spectrum satisfies “1≤peak intensity ratio A/peak intensity ratio B≤7” in the front surface and the surface of the support 22 can be stably manufactured.

The inorganic layer 26 is also preferably formed by R-to-R.

(Second Organic Layer 28: Protective Organic Layer)

The second organic layer 28 is provided on the inorganic layer 26.

The second organic layer 28 is provided as a preferable embodiment, and is a protective organic layer that protects the inorganic layer 26. By providing the second organic layer 28, for example, in the case where the gas barrier film 10 is used for a solar cell module, damage to the inorganic layer 26 in the step for manufacturing the solar cell module can be prevented.

As the second organic layer 28, an organic layer similar to the above-mentioned first organic layer 24 is suitably exemplified.

The thickness of the second organic layer 28 can be appropriately set according to the components of a second organic layer forming composition that forms the second organic layer 28 so that the inorganic layer 26 can be sufficiently protected.

The thickness of the second organic layer 28 is preferably 0.5 to 30 μm and more preferably 1 to 15 μm. By setting the thickness of the second organic layer 28 to 0.5 μm or more, it is possible to prevent damage caused by applying an external force to the inorganic layer 26. By setting the thickness of the second organic layer 28 to 30 μm or less, a thin gas barrier film 10 can be obtained, and a gas barrier film 10 having good flexibility and transparency can be obtained.

The second organic layer 28 can be formed by a known method.

As one example, the second organic layer 28 can be formed by applying a second organic layer forming composition to the inorganic layer 26 and drying the composition. Further, the second organic layer 28 can be formed by polymerizing (crosslinking) the organic compound in the second organic layer forming composition by irradiation with ultraviolet rays as necessary.

In addition, the second organic layer 28 is also preferably formed by R-to-R.

The gas barrier film 10 preferably has high light transmittance and low haze. As described above, since the support 22 in the gas barrier film 10 according to the embodiment of the present invention is less altered by vacuum ultraviolet rays and the transparency of the support 22 is high, the gas barrier film has high transparency and high light transmittance.

Specifically, the total light transmittance of the gas barrier film 10 is preferably 85% or more, and more preferably 90% or more. The haze of the gas barrier film 10 is preferably 1.5% or less and more preferably 1.0% or less.

The total light transmittance of the gas barrier film 10 can be measured according to JIS K 7361 using a commercially available measuring device such as NDH5000 or SH-7000 manufactured Nippon Denshoku Industries Co., Ltd.

The haze of the gas barrier film 10 can be measured according to JIS K 7136 (1997) using a commercially available measuring device such as NDH 5000 manufactured by Nippon Denshoku Industries Co., Ltd.

The thermal shrinkage rate of gas barrier film 10 is preferably 2% or less and more preferably 1.5% or less.

By setting the thermal shrinkage rate of the gas barrier film 10 to 2% or less, it is possible to prevent the support 22 from extending in the manufacturing step exposed to a severe environment. Thus, it is possible to prevent damage to the inorganic layer 26.

The thermal shrinkage rate of gas barrier film 10 can be measured as follows.

A sample is prepared by cutting the gas barrier film 10 to be measured for the thermal shrinkage rate so as to a size of measurement direction 250 mm×width 50 mm. Two holes are opened with an interval of 200 mm in the prepared sample, the sample is left for 12 hours in an environment of a temperature 25° C. and a relative humidity of 60% RH, and the humidity is controlled. After the humidity is controlled, a distance between the two holes of the sample is measured using a pin gauge, and the length is set to L1. After L1 is measured, the sample is heated to a temperature of 150° C. for 30 minutes. After the sample is heated for 30 minutes, the sample is left for 12 hours in an environment of a temperature 25° C. and a relative humidity of 60% RH and the humidity is controlled gain. After the humidity is controlled, distance between the two holes of the sample is measured using a pin gauge again and the length is set to L2.

The thermal shrinkage rate [%] of the gas barrier film 10 to be measured is determined by the following equation.

Thermal shrinkage rate [%]=100×[(L2−L1)/L1]

The thermal shrinkage rate of the gas barrier film 10 can be set to 2% or less by performing a heat treatment (annealing) on the support 22 in advance to saturate the thermal shrinkage.

Another method for setting the thermal shrinkage rate of the gas barrier film 10 to 2% or less is, for example, a method in which in the formation of the first organic layer 24 and/or the formation of the second organic layer 28, the drying temperature of the composition forming each layer is set to 100° C. or higher. According to this method, since it is not necessary to separately perform a heat treatment, the method is advantageous in terms of the number of manufacturing steps, productivity, manufacturing cost, and the like.

(Method for Manufacturing Gas Barrier Film)

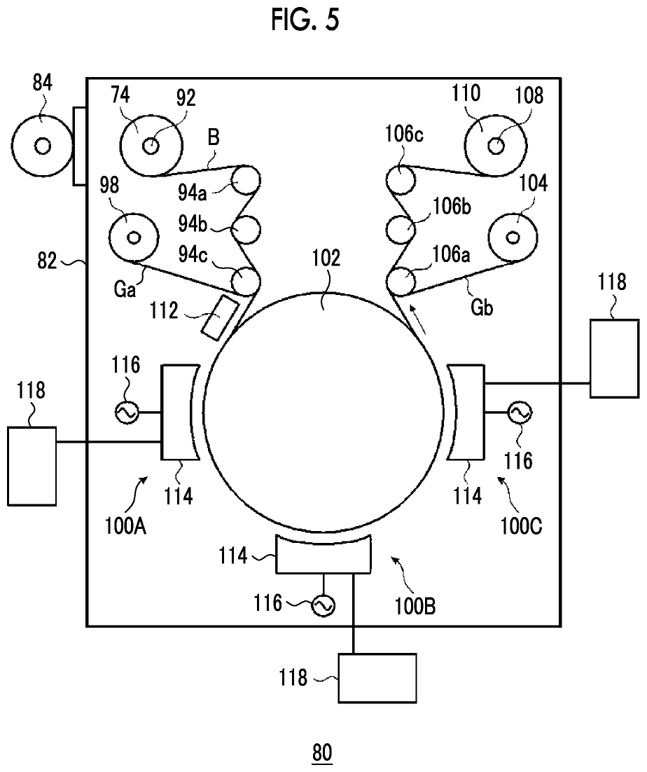

The gas barrier film 10 is preferably manufactured using R-to-R. The preferable manufacturing method of the gas barrier film 10 is described using FIGS. 4 and 5.

FIG. 4 shows an organic film forming apparatus 40.

The organic film forming apparatus 40 is an apparatus which forms an organic layer by R-to-R, and for example, further forms the first organic layer 24 or the second organic layer 28. The organic film forming apparatus 40 includes a rotating shaft 52, pairs of transport rollers 54a and 54b, a coating unit 56, a drying unit 58, a light irradiation unit 60, a winding shaft 62, a collection roll 64, and a supply roll 66.

The drying unit 58 has a drying unit 58a that performs heating and drying from the front side (the first organic layer forming composition side, the upper side in FIG. 4), and a drying unit 58b that performs heating and drying from the rear side (the support 22 side), and can perform heating from both the front side and the rear side.

As a heating method in the drying unit 58, a known method for heating a sheet-like material can be used. For example, a hot air drying may be performed by the drying unit 58a, and drying may be performed by the heat roller (pass roller having a heating mechanism) by the drying unit 58b.

Hereinafter, a method for forming the first organic layer 24 using the organic film forming apparatus 40 will be described.

The first organic layer 24 is formed by, while transporting a sheet A, which is a long film formation target, in a longitudinal direction, applying the first organic layer forming composition to the sheet.

First, a roll 72 formed by winding the long sheet A (support 22) is loaded on the rotating shaft 52. Next, the sheet A is drawn out from the roll 72 and transported along a transport path. The transport path passes from the roll 72 to the winding shaft 62 through the pair of transport rollers 54a, the coating unit 56, the drying unit 58, the light irradiation unit 60, and the pair of transport rollers 54b in order.

The first organic layer forming composition is applied to the surface of the sheet A drawn out from the roll 72 in the coating unit 56. Examples of the coating method in the coating unit 56 include a die coating method, a dip coating method, an air knife coating method, a curtain coating method, a roller coating method, a wire bar coating method, and a gravure coating method. For example, in the case where the sheet A has a protective film Gb as in the case of forming the second organic layer 28, the protective film Gb is peeled off from the support at the pair of transporting rollers 54 a and collected by the collection roll 64.

Next, the sheet A on which the first organic layer forming composition is applied is heated by the drying unit 58. Thus, the organic solvent is removed from the first organic layer forming composition, and the first organic layer forming composition is dried.

The first organic layer forming composition is dried at, for example, 100° C. or higher (drying step). Specifically, in the drying unit 58, heating is performed so that at least one of the surface temperature of the support 22 and the temperature of the applied first organic layer forming composition is 100° C. or higher. The surface temperature of the support 22 refers to the temperature of the surface (rear surface) to which the first organic layer forming composition is not applied.

The drying temperature of the first organic layer forming composition is preferably 100° C. or higher.

By drying the first organic layer forming composition at 100° C. or higher, the thermal shrinkage of the support 22 is saturated. As a result, the thermal shrinkage rate of the gas barrier film 10 is 2% or less and the support 22 can be prevented from being deformed in the manufacturing step exposed to a severe environment.

Next, the sheet A is irradiated with ultraviolet rays and the like by the light irradiation unit 60. Thus, the organic compounds (graft copolymer and acrylate monomer) are polymerized (crosslinked) to form the first organic layer 24. The polymerization of the organic compound may be carried out in an inert atmosphere such as a nitrogen atmosphere, as necessary.

Next, a protective film Ga fed from the supply roll 66 is laminated on the first organic layer 24 by the pair of transport rollers 54b. The protective film Ga is a protective film for protecting the first organic layer 24 (second organic layer 28). The sheet A on which the protective film Ga is laminated is wound around a winding shaft 62 to obtain a roll 74.

FIG. 5 shows an inorganic film forming apparatus 80.

The inorganic film forming apparatus 80 is an apparatus which forms an inorganic layer by R-to-R, and forms the inorganic layer 26, for example.

The inorganic film forming apparatus 80 has a vacuum chamber 82. The vacuum chamber 82 includes evacuation means 84. By driving the evacuation means 84, the internal pressure of the inorganic film forming apparatus 80 (vacuum chamber 82) can be adjusted.

In the vacuum chamber 82, a rotating shaft 92, pass rollers 94a to 94c, a collection roll 98, a first film forming unit 100A, a second film forming unit 100B, a third film forming unit 100C, a drum 102, a supply roll 104, pass rollers 106a to 106c, and a winding shaft 108 are provided. The inorganic film forming apparatus 80 is provided for carrying out the film forming method according to the embodiment of the present invention, and in the vacuum chamber 82, heating means 112 for heating a sheet B which is a base material of the inorganic layer is provided on an upstream side of the uppermost first film forming unit 100A.

The film forming method includes a step of heating a base material, and a step of forming a film on the surface of the base material under conditions different from each other by at least two film forming units including a first plasma CVD unit and a second plasma CVD unit disposed on a downstream side of the first plasma CVD unit in the transport direction, and a step of heating the base material, a step of forming an inorganic layer on the base material using hydrogen as a raw material gas by the first plasma CVD unit, and a step of forming another inorganic layer on the base material on which the organic layer is formed by the second plasma CVD unit are carried out in this order.

In such an inorganic film forming apparatus 80, while transporting the longitudinal direction of the long base material (sheet B) having the first organic layer 24 formed on the support 22 in the transport direction, a film forming treatments is performed on the first organic layer 24 of the sheet B to form an inorganic layer 26 including at least one of oxygen, nitrogen, and carbon, silicon, and hydrogen.

First, the roll 74 is loaded on the rotating shaft 92. Next, the sheet B drawn out from the roll 74 is transported on the transport path, and is allowed to pass through a predetermined transport path which reaches the winding shaft 108 through the pass rollers 94a to 94c, the drum 102, and the pass rollers 106a to 106c.

The sheet B drawn out from the roll 74 is guided by the pass rollers 94a to 94c and while being wound around the drum 102 and transported along a predetermined path, is treated by two or more film forming units of the first film forming unit 100A, the second film forming unit 100B, and the third film forming unit 100C. Thus, the inorganic layer 26 is formed on the surface of the first organic layer 24. In the drum 102, temperature control means is incorporated, and the sheet B is preferably treated by two or more film forming units of the first film forming unit 100A, the second film forming unit 100B, and the third film forming unit 100C while being cooled by the drum 102.

In the case where the sheet B has the protective film Ga, the protective film Ga is peeled off from the sheet B (first organic layer 24) in the last pass roller 94 c and collected by the collection roll 98.

The treatment method (film forming method) in the first film forming unit 100A, the second film forming unit 100B and the third film forming unit 100C is, for example, capacitively coupled plasma-chemical vapor deposition (CCP-CVD, hereinafter, also referred to as “plasma CVD”).

The first film forming unit 100A, the second film forming unit 100B and the third film forming unit 100C have the same configuration and each have a shower electrode 114 constituting an electrode pair with the drum 102, a high frequency power supply 116, and gas supply means 118. The shower electrode 114 is a known shower electrode used for plasma CVD, which has an opening for supplying a raw material gas to the surface facing the drum 102. The high frequency power supply 116 supplies plasma excitation power to the shower electrode 114, and is a known high frequency power supply used for plasma CVD. The gas supply means 118 is provided for supplying the raw material gas to the shower electrode 114, and is known gas supply means used for plasma CVD.

In the inorganic film forming apparatus 80, the inorganic layers are formed under different film formation conditions so that the hydrogen atom concentration of the inorganic layer formed by the film forming unit on the downstream side is lower than the hydrogen atom concentration of the inorganic layer formed by the film forming unit on the upstream side. As an example, an example in which the inorganic layers 26 are formed using the first film forming unit 100A and the third film forming unit 100C is mentioned. At this time, the inorganic layer 26 is formed under film formation conditions in which the hydrogen concentration is lower in the inorganic layer formed in the third film forming unit 100C than in the inorganic layer formed in the first film forming unit 100A.

In the inorganic film forming apparatus 80, the inorganic layers 26 may be formed using the first film forming unit 100A and the second film forming unit 100B, the inorganic layer 26 may be formed using the second film forming unit 100B and the third film forming unit 100C, and the inorganic layer 26 may be formed using all of the first film forming unit 100A to the third film forming unit 100C.

However, in the film forming method according to the embodiment of the present invention described later, even in the case of forming the inorganic layer 26 by any two or more film forming units of the first film forming unit 100A to the third film forming unit 100C, the inorganic layers formed by each unit are the same inorganic layers except that the hydrogen concentration is different.

In the sheet B on which the inorganic layer 26 is formed, the protective film Gb fed from the supply roll 104 is laminated on the inorganic layer 26 at the pass roller 106a. The protective film Gb is a film for protecting the inorganic layer 26.

The sheet B on which the protective film Gb is formed is guided by the pass rollers 106a to 106c and transported to the winding shaft 108, and the sheet B on which the protective film Gb is laminated is wound around the winding shaft 108 to obtain a roll 110.

After the inorganic layer 26 is formed, the vacuum chamber 82 is opened to the atmosphere to introduce clean dry air. The roll 110 is then removed from the vacuum chamber 82.

In the case where the second organic layer 28 is formed, the roll 110 is again loaded on the rotating shaft 52 of the organic film forming apparatus 40 in order to form the second organic layer 28.

The second organic layer 28 can be formed in the same manner except that the second organic layer forming composition is applied instead of applying the first organic layer forming composition to the sheet A in the formation of the first organic layer 24.

In the case where the second organic layer 28 is formed, the second organic layer forming composition is dried at, for example, 100° C. or higher (drying step).

In the case where a plurality of combinations of the first organic layer 24 and the inorganic layer 26 are formed, the formation of the first organic layer 24 and the formation of the inorganic layer 26 may be repeated according to the number of combinations. The same applies to the formation of the second organic layer 28.

For the method for manufacturing the gas barrier film 10, the method for forming an organic layer and an inorganic layer by R-to-R described in JP2013-166298A can be referred to.

The method for manufacturing the gas barrier film 12 is the same as the method for manufacturing the gas barrier film 10 except that the formation of the first organic layer 24 and the formation of the inorganic layer 26 are repeated.

Here, in the case where the gas barrier film 10 according to the embodiment of the present invention is manufactured, the inorganic film forming apparatus 80 forms the inorganic layer 26 by the film forming method according to the embodiment of the present invention.

Thus, it is possible to stably manufacture a gas barrier film 10 in which the hydrogen concentration on the support side 26L is 10% to 45% by atom, the hydrogen concentration in the surface side 26U is 5% to 35% by atom, the inorganic layer 26 in which the hydrogen concentration is lower than the hydrogen concentration on the support side 26L is provided, and further, the peak intensity ratios of the infrared absorption spectra of the front surface and the rear surface of the support 22 satisfy “1≤peak intensity ratio A/peak intensity ratio B≤7”.

The film forming method according to the embodiment of the present invention is a method for forming the inorganic layer 26 using two or more film forming units in an apparatus for forming a film by plasma CVD in R-to-R, which has a plurality of (three in the illustrated example) film forming units in the transport direction of the sheet B like the inorganic film forming apparatus 80.

In the formation of the inorganic layer 26 using such a plurality of film forming units, a heat treatment of the sheet B before the formation of the inorganic layer by the uppermost film forming unit forming the inorganic layer 26 and/or the formation of the inorganic layer 26 using hydrogen gas as a raw material gas is performed and further, in the plurality of film forming units for forming the inorganic layer 26, the inorganic layers 26 are formed under different film formation conditions.

Specifically, the different conditions in the plurality of film forming units forming the inorganic layer 26 are film formation conditions that the hydrogen concentration of the inorganic layer formed by the film forming unit on the downstream side is lower than the hydrogen concentration of the inorganic layer formed by the film forming unit on the upstream side.

As described above, in the case where an inorganic layer containing silicon is formed by plasma CVD, vacuum ultraviolet rays are generated, and the vacuum ultraviolet rays alter the support 22. As described above, the amount of vacuum ultraviolet rays generated is increased in a state in which the decomposition of the raw material gas proceeds, and in the above state, a high density inorganic layer having a low hydrogen concentration can be formed.

However, even in the case of forming the region of the support side 26L having a high hydrogen concentration in the formation of the inorganic layer 26, the vacuum ultraviolet rays are generated, and the alteration of the support 22 by the vacuum ultraviolet rays proceeds. Particularly, at the time of forming the region of the support side 26L in the formation of the inorganic layer 26, the support 22 (first organic layer 24) is subjected to film formation in a state in which the support is hardly protected against vacuum ultraviolet rays.

Accordingly, by simply forming the region of the support side 26L under the film formation conditions such that the hydrogen concentration becomes high, it is not possible to sufficiently prevent the alteration of the support 22 by vacuum ultraviolet rays, and the gas barrier film 10 according to the embodiment of the present invention in which the peak intensity ratios of the infrared absorption spectra of the front surface and the rear surface of the support 22 satisfy “1≤peak intensity ratio A/peak intensity ratio B≤7” cannot be manufactured.

On the other hand, in the film forming method according to the embodiment of the present invention, the heat treatment of the sheet B before the film formation by the uppermost film forming unit for forming the inorganic layer 26 and/or the formation of the inorganic layer 26 using hydrogen gas as a raw material gas is performed.

In the case where film formation is performed by plasma CVD, the temperature of the material to be film-formed increases with the progress of film formation. Particularly, in the apparatus having a plurality of film forming units, such as the inorganic film forming apparatus 80, the temperature of the film forming material is gradually increased toward the film forming unit on the downstream side. In the case where the temperature of the film forming material increases, the film quality fluctuates due to the temperature increase.

Therefore, usually, in order to form a uniform film in the thickness direction, the inorganic layer is formed while cooling the support, for example, by cooling the drum 102 as described above. In the inorganic film forming apparatus 80, in order to cool the sheet B to be heated as being moved toward the downstream side, preferably, while the sheet B is cooled by cooling the drum 102, the inorganic layer 26 is formed.

In contrast, in the case where the inorganic layer 26 is formed by the film forming method according to the embodiment of the present invention, in the inorganic film forming apparatus 80, the sheet B is heated by the heating means 112 disposed immediately on the upstream side of the first film forming unit 100A, and the formation of an inorganic layer having a high hydrogen concentration, which is a part of the inorganic layer 26, by the film forming by the film forming unit on the downstream side, is performed on the heated sheet B in the first film forming unit 100A.

In the case where the film formation of the inorganic layer is performed in a state in which the sheet B is heated to a high temperature, the active species generated by the decomposition of the raw material gas is easily moved on the sheet B (surface to be formed). Therefore, since the active species is moved and deposited at the optimum position without depositing at the reached position, the coatability of the sheet B becomes high, and the entire surface of the sheet B can be rapidly covered with the inorganic layer having a high hydrogen concentration. As described above, in the inorganic layer 26, the support side 26L having a high hydrogen concentration also acts as a protective layer against vacuum ultraviolet rays on the support 22 (and the first organic layer 24). Therefore, by heating the sheet B by the heating means 112, after the film formation of the inorganic layer 26 is started by the first film forming unit 100A, the entire surface of the sheet B can be quickly covered with the protective layer against vacuum ultraviolet rays, and thus the alteration of the support 22 by vacuum ultraviolet rays can be prevented. In addition, since the entire surface of the sheet B can be rapidly covered by the inorganic layer having a high hydrogen concentration, and the thin film can be flattened, the film forming time can be shortened. In this respect, the alteration of the support 22 due to the vacuum ultraviolet light can be prevented.

As a result, the gas barrier film 10 according to the embodiment of the present invention in which the peak intensity ratios of the infrared absorption spectra of the front surface and the rear surface of the support 22 satisfy “1≤peak intensity ratio A/peak intensity ratio B≤7 can be manufactured.

Further, by heating the sheet B, an inorganic layer having a certain degree of density while appropriately containing hydrogen can be formed. Further, since a dehydrogenation reaction also proceeds on the surface of the sheet B, the hydrogen is reduced in the support side 26L of the inorganic layer 26. Therefore, the gas barrier properties of the inorganic layer 26 can be improved by forming the inorganic layer 26 by the first film forming unit 100A after heating the sheet B by the heating means 112.

In formation of the inorganic layer by normal plasma CVD in which film formation is performed by the first film forming unit 100A, without heating the sheet B by the heating means 112, since there is no movement of the active species on the surface of the sheet B, the active species is deposited at the reached position. Therefore, since the film formation rate is fast, the density is low, and further, the coatability is poor, it takes time until the inorganic layer, that is, the protective layer is formed on the entire surface, and in the region where the inorganic layer is not formed, the alteration of the support 22 by vacuum ultraviolet rays proceeds.

In addition, as compared to the case where the sheet B is heated by the heating means 112, the density of the inorganic layer is low, further, the dehydrogenation reaction on the surface of the sheet B does not proceed, and thus the gas barrier properties of the inorganic layer are also low.

The heating method by the heating means 112 is not particularly limited, known heating methods for heating the sheet-like material to be transported, such as heating with warm air, heating with a heat roller (pass roller having a heating mechanism), and heating with a heater, can all be used.

Further, the heating temperature of the sheet B by the heating means 112 is not particularly limited. The heating of the sheet B by the heating means 112 is preferably performed so that the temperature of the surface (the film forming surface) of the sheet B is preferably 40° C. or higher, more preferably 60° C. or higher, and even more preferably 80° C. or higher. By heating the sheet B to have a surface temperature of 40° C. or higher, the above-described effect of the heating can be exhibited in the step. Thus, the alteration of the support 22 can be suppressed and gas barrier properties, and the like can be improved.

The upper limit of the heating temperature of the sheet B by the heating means 112 is not particularly limited, and may be set to a temperature or lower at which the support 22 is not damaged, deformed or the like depending on the support 22.

Further, by forming the inorganic layers 26 by using hydrogen gas as a raw material gas in the first film forming unit 100A and the third film forming unit 100C, the coatability is improved, and thus the inorganic layer can be formed rapidly on the entire surface of the film formation surface in each unit.

Particularly, in the first film forming unit 100A, by introducing hydrogen gas, the entire surface of the sheet B can be rapidly covered with the inorganic layer having a high hydrogen concentration. Therefore, as in the case where the sheet B is heated by the heating means 112 described above, after the film formation of the inorganic layer 26 is started by the first film forming unit 100A, the entire surface of the sheet B is rapidly covered with a protective layer, that is, an inorganic layer having a high hydrogen concentration, against vacuum ultraviolet rays, and thus the alteration of the support 22 by vacuum ultraviolet rays can be prevented. In addition, since the entire surface of the sheet B can be rapidly covered by the inorganic layer having a high hydrogen concentration and the thin film can be flattened, the film formation time can be shortened. In this respect, the alteration of the support 22 by vacuum ultraviolet rays can be prevented.

As a result, the gas barrier film 10 according to the embodiment of the present invention in which the peak intensity ratios of the infrared absorption spectra of the front surface and the rear surface of the support 22 satisfy “1≤peak intensity ratio A/peak intensity ratio B≤7 can be manufactured.

In the case of using hydrogen gas as a raw material gas in the film formation of the inorganic layer 26, the amount (addition amount) of hydrogen gas supplied in each film forming unit is not particularly limited, and may be set appropriately according to the kind of the inorganic layer 26 to be formed, the hydrogen concentration of the support side 26L and the surface side 26U, and the like.

Further, the amount of hydrogen gas supplied by each film forming unit may be the same or different. However, even in the case where any film forming unit is used to form the inorganic layer 26, it is necessary to consider the amount of hydrogen gas supplied in each film forming unit so that the hydrogen concentration of the inorganic layer to be formed becomes lower toward the film forming unit on the downstream side.

In the film forming method according to the embodiment of the present invention, only one or both of the heating of the sheet B by the heating means 112 and the formation of the inorganic layer 26 using hydrogen gas as a raw material gas may be performed.

However, in the viewpoint of being capable of obtaining the inorganic layer 26 (gas barrier film 10) having higher gas barrier properties, which can suitably suppress the alteration of the support 22, it is preferable that both the heating of the sheet B by the heating means 112 and the formation of the inorganic layer 26 using hydrogen gas as a raw material gas are performed.

In the film forming method according to the embodiment of the present invention, in addition to the heating of the sheet B by the heating means 112 and/or the formation of the inorganic layer 26 using hydrogen gas as a raw material gas, the inorganic layers are formed under different film formation conditions in the plurality of film forming units for forming the inorganic layer 26.

For example, in the case of forming the inorganic layers 26 using the first film forming unit 100A and the third film forming unit 100C, the first film forming unit 100A necessarily forms a part of the support side 26L, and the third film forming unit 100C necessarily forms a part of the surface side 26U having a hydrogen concentration lower than the hydrogen concentration of the support side 26L. Accordingly, the inorganic layers 26 can be formed under different film formation conditions by the two film forming units so that the hydrogen atom concentration of the inorganic layer formed by the film forming unit on the downstream side is lower than the hydrogen atom concentration of the inorganic layer formed by the film forming unit on the upstream side.

The inorganic layers 26 can be formed under different film formation conditions in which at least one of the plasma excitation power, the film formation pressure, the frequency of the plasma excitation power, the amount of hydrogen supplied as a raw material gas, or the temperature of the sheet B is different in the film forming unit on the upstream side and the film forming unit on the downstream side so that the hydrogen atom concentration of the inorganic layer formed by the film forming unit on the downstream side is lower than the hydrogen atom concentration of the inorganic layer formed by the film forming unit on the upstream side.

More specifically, examples of the film formation conditions include a film formation condition in which the plasma excitation power supplied to the shower electrode 114 by the high frequency power supply 116 is set to be higher than in the film forming unit on the downstream side than in the film forming unit on the upstream side out of the two film forming units, a film formation condition in which the film forming pressure is set to be lower in the film forming unit on the downstream side than in the film forming unit on the upstream side, a film formation condition in which the frequency of plasma excitation power supplied to the shower electrode 114 by the high frequency power supply 116 is set to be higher in the film forming unit on the downstream side than in the film forming unit on the upstream side, a film formation condition in which the amount of hydrogen gas supplied by the gas supply means 118 as a raw material gas is smaller in the film forming unit on the downstream side than in the film forming unit on the upstream side, and a film formation condition in which the temperature of the sheet B lower than the film forming unit on the downstream side than the film forming unit on the upstream side by providing cooling means near the circumferential surface of the drum 102, and a film forming method including at least one condition among these is preferable.

In the plurality of film forming units for forming the inorganic layer 26, by changing at least one of the plasma excitation power, the film formation pressure, the frequency of the plasma excitation power, the amount of hydrogen supplied as a raw material gas, or the temperature of the sheet B in each film forming unit as described above, the inorganic layer 26 in which the hydrogen concentration on the support side 26L is 10% to 45% by atom and the hydrogen concentration on the surface side 26U is 5% to 35% by atom and is lower than the hydrogen concentration on the support side 26L can be formed.

The amount of change in the conditions such as the plasma excitation power, the film formation pressure, the frequency of the plasma excitation power, the amount of hydrogen supplied as a raw material gas, or the temperature of the sheet B may be appropriately set so that the desired hydrogen concentrations on the support side 26L and the surface side 26U can be obtained within the range of not affecting the film quality of the formed inorganic layer 26.

In the inorganic film forming apparatus 80, the film thickness of the inorganic layer formed in each film forming unit is not particularly limited and may be set appropriately according to the film thickness of the inorganic layer 26 to be formed.

For example, in the case where the inorganic layers 26 having a thickness of 50 nm is formed using the first film forming unit 100A and the second film forming unit 100B, each inorganic layer having a thickness of 25 nm may be formed by the first film forming unit 100A and the second film forming unit 100B, an inorganic layer having a thickness of 10 nm may be formed by the first film forming unit 100A, and an inorganic layer having a thickness of 40 nm may be formed by the third film forming unit 100C, and conversely, an inorganic layer having a thickness of 40 nm may be formed by the first film forming unit 100A, and an inorganic layer having a thickness of 10 nm may be formed by the third film forming unit 100C.

That is, in the film forming method according to the embodiment of the present invention, in any of the plurality of film forming units, even in a case where an inorganic layer of any thickness is formed, the hydrogen concentration on the support side 26L below the center shown by the dashed dotted line in FIG. 3 in the thickness direction of the formed inorganic layer 26 may be 10% to 45% by atom and the hydrogen concentration on the surface side 26U above the center may be 5% to 35% by atom, and may be lower than the hydrogen concentration on the support side 26L.

Hereinabove, the gas barrier film and the film forming method according to the embodiments of the present invention are described in detail, but the present invention is not limited to Examples. Various modifications or alterations may be made within a range not departing from the gist of the present invention.

### EXAMPLES

Hereinafter, the present invention will be described in more detail with reference to specific examples. The present invention is not limited to the specific examples shown below.

### Example 1

<<Support>>

As the support 22, a PET film (COSMO SHINE A4300 manufactured by Toyobo Co., Ltd.) having a width of 1,000 mm, a thickness of 100 μm, and a length of 100 m was used.

<<Formation of First Organic Layer (Underlying Organic Layer)>>

TMPTA (manufactured by Daicel-Cytec Co., Ltd.) and a photopolymerization initiator (ESACURE KTO 46 manufactured by Lamberti S.p.A.) were weighed such that the mass ratio thereof was 95:5. These were dissolved in methyl ethyl ketone (MEK) such that the concentration of the solid content was 15% by mass, thereby preparing a first organic layer forming composition.

The coating unit 56 of the organic film forming apparatus 40 was filled with the first organic layer forming composition. In addition, the roll 72 formed by winding the support 22 in a roll shape was loaded in the rotating shaft 52, and the support 22 drawn out from the roll 72 was transported in the transport path. Further, the supply roll 66 formed by winding the protective film Ga formed of PE was loaded at a predetermined position, and the protective film Ga was laminated on the first organic layer 24 at the pair of transport rollers 54b.

In the organic film forming apparatus 40, while transporting the support 22 (sheet A) in the longitudinal direction, the first organic layer forming composition was applied by the coating unit 56, and the first organic layer forming composition was dried by the drying unit 58. As the coating unit 56, a die coater was used. The heating temperature in the drying unit 58 was set to 50° C. and the passing time in the drying unit 58 was set to 3 minutes.

Next, in the light irradiation unit 60, the first organic layer 24 was formed by irradiating the support 22 with ultraviolet rays (total irradiation amount: approximately 600 mJ/cm²) to cure the first organic layer forming composition. After the protective film Ga was laminated on the surface of the first organic layer 24 at the pair of transport rollers 54b, the support 22 on which the first organic layer 24 was formed was wound around the winding shaft 62 to obtain the roll 74. The thickness of the formed first organic layer 24 was 1 μm.

<<Formation of First Inorganic Layer>>

The roll 74 formed by winding the support 22 on which the first organic layer 24 was formed (sheet B) was loaded on the rotating shaft 92 of the inorganic film forming apparatus 80, and the sheet B drawn out from the roll 74 was inserted into a predetermined transport path reaching the winding shaft 108 through the pass rollers 94a to 94c, the drum 102, and the pass rollers 106a to 106c. Further, the supply roll 104 formed by winding the protective film Gb formed of PE was loaded at a predetermined position, and the protective film Gb was laminated on the inorganic layer 26 at the pass roller 106a.

After the protective film Ga was peeled off by the pass roller 96c while transporting the sheet B drawn out from the roll 74 in the longitudinal direction, a silicon nitride film was formed on the first organic layer 24 as the inorganic layer 26. In the sheet B on which the inorganic layer 26 was formed, the protective film Gb was laminated on the surface of the inorganic layer 26 at the pass roller 106a and then wound around the winding shaft 108. In this manner, the roll 110 formed by winding a laminate in which the protective film Gb was laminated on the inorganic layer 26 of the gas barrier film in which the first organic layer 24 and the inorganic layer 26 were formed on the support 22 was obtained.

The first film forming unit 100A and the third film forming unit 100C were used to form the inorganic layers 26 (silicon nitride films).

As raw material gases, silane gas, ammonia gas, and hydrogen gas were used. The amounts of the raw material gases supplied were 100 sccm of silane gas, 200 sccm of ammonia gas, and 1000 sccm of hydrogen gas in both the first film forming unit 100A and the third film forming unit 100C.

The plasma excitation power was set to 2000 W for the first film forming unit 100A and 3000 W for the third film forming unit 100C. The frequency of the plasma excitation power was set to 13.56 MHz.

The heating temperature of the sheet B (the surface temperature of the first organic layer 24 of the sheet B) by the heating means 112 was set to 80° C., the temperature of the drum 102 was set to 0° C., and the film formation pressure was 60 Pa. The heating temperature by the heating means 112 was measured by THERMO LABEL.

The film thickness of the formed inorganic layer 26 was 50 nm.

### Examples 2 to 6 and Comparative Examples 1 to 9

Gas barrier films were prepared by forming the first organic layer 24 and the inorganic layer 26 (silicon nitride film) on the support 22, the protective film Gb was laminated on the surface of the inorganic layer 26, and the laminate was wound in the same manner as in Example 1 except that in the formation of the inorganic layer 26 (silicon nitride film), the film forming unit used, the amount of each raw material gas supplied, the addition of nitrogen gas (or argon gas) to the raw material gas, plasma excitation power, heating by the heating means 112, and the temperature of the drum 102 were changed as shown in Table 1 below.

In the preparation of each gas barrier film, the film thickness of the inorganic layer 26 was made to be 50 nm by adjusting the transport speed of the sheet B in the inorganic film forming apparatus 80.

### Examples 7 to 9 and Comparative Examples 10 to 13

Gas barrier films were prepared by forming the first organic layer 24 and the inorganic layer 26 (silicon nitride film) on the support 22, the protective film Gb was laminated on the surface of the inorganic layer 26, and the laminate was wound in the same manner as in Example 1 except that a silicon oxide film was formed as the inorganic layer 26 using hexamethyldisilazane (HMDS), oxygen gas, and hydrogen gas as the raw material gases instead of silane gas, ammonia gas and hydrogen gas (or nitrogen gas).

In each example, the amounts of the respective raw material gases supplied in the formation of the inorganic layer 26 (silicon oxide film), the plasma excitation power, the heating by the heating means 112, and the temperature of the drum 102 were set as shown in Table 1 below.

In addition, in the preparation of each gas barrier film, the film thickness of the inorganic layer 26 was made to be 50 nm by adjusting the transport speed of the sheet B in the inorganic film forming apparatus 80.

### Example 10

A gas barrier film was prepared in the same manner as in Example 1 except that a silicon oxide film was formed as the inorganic layer 26 using a general film forming apparatus for performing film formation by an atomic layer deposition method using R-to-R.

The inorganic layer 26 was formed using bis(ethylmethylamino)silane (BEMAS), oxygen gas, hydrogen gas, and argon gas as raw material gases.

In the film formation of the inorganic layer 26, in the first half, the amounts of the raw material gases supplied were 50 sccm of BEMAS, 50 sccm of oxygen gas, 100 sccm of hydrogen gas and 500 sccm of argon gas, the high frequency power was 200 W, and the support temperature was 80° C. In the second half, the amounts of the raw material gases supplied were 50 sccm of BEMAS, 50 sccm of oxygen gas, 20 sccm of hydrogen gas and 500 sccm of argon gas, the high frequency power was 300 W, and the support temperature was 40° C.

In the formation of the inorganic layer 26, the film formation time in the first half and the second half were the same, and the film thickness of the inorganic layer 26 was 50 nm.

In the formation of the inorganic layer 26 by the atomic layer deposition method, argon gas was constantly supplied as a carrier gas. Further, an operation of supplying and adsorbing BEMAS to the sheet B and supplying oxygen gas+hydrogen gas to apply a high frequency power were alternately performed to form a silicon oxide film. By supplying high frequency power by supplying oxygen gas+hydrogen gas, O radicals and H radicals were generated to form Si—O bonds and Si—H bonds with BEMAS adsorbed in advance, and thus a silicon oxide film was formed.

The preparation of the gas barrier films in Examples 1 to 10 and Comparative Examples 1 to 13 above are collectively shown in Table 1 below.

TABLE 1

| | | Film forming unit 100A | | | | | Film forming unit 100B | | | | |
|---|---|---|---|---|---|---|---|---|---|---|---|
| | | SiH₄ | NH₃ | H₂ | N₂ | Power | SiH₄ | NH₃ | H₂ | N₂ | Power |
| | Inorganic layer | [sccm] | [sccm] | [sccm] | [sccm] | [W] | [sccm] | [sccm] | [sccm] | [sccm] | [W] |
| Example 1 | SiN | 100 | 200 | 1000 | — | 2000 | — | — | — | — | — |
| Example 2 | | 100 | 200 | 1000 | — | 1000 | — | — | — | — | — |
| Example 3 | | 100 | 200 | 5000 | — | 2000 | — | — | — | — | — |
| Comparative Example 1 | | 100 | 200 | 1000 | — | 3000 | — | — | — | — | — |
| Comparative Example 2 | | 100 | 200 | 1000 | — | 2000 | — | — | — | — | — |
| Comparative Example 3 | | 100 | 200 | 0 | — | 2000 | — | — | — | — | — |
| Comparative Example 4 | | 100 | 200 | 1000 | — | 2000 | — | — | — | — | — |
| Comparative Example 5 | | 100 | 200 | 1000 | — | 2000 | — | — | — | — | — |
| Comparative Example 6 | | 100 | 200 | 1000 | — | 2000 | — | — | — | — | — |
| Comparative Example 7 | | 25 | 15 | 0 | 200 | 1000 | 50 | 100 | 0 | 330 | 500 |
| Comparative Example 8 | | 50 | 100 | 0 | 330 | 500 | — | — | — | — | — |
| Comparative Example 9 | | 100 | 200 | 1000 | — | 2000 | 100 | 200 | 1000 | — | 2000 |
| Example 4 | | 100 | 200 | 5000 | — | 1000 | — | — | — | — | — |
| Example 5 | | 100 | 200 | 5000 | — | 2500 | — | — | — | — | — |
| Example 6 | | 100 | 200 | 1000 | — | 2000 | — | — | — | — | — |

| | Film forming unit 100C | | | | | | |
|---|---|---|---|---|---|---|---|
| | SiH₄ | NH₃ | H₂ | N₂ | Power | Heating means | Drum |
| | [sccm] | [sccm] | [sccm] | [sccm] | [W] | [° C.] | [° C.] |
| Example 1 | 100 | 200 | 1000 | — | 3000 | 80 | 0 |
| Example 2 | 100 | 200 | 1000 | — | 3000 | 80 | 0 |
| Example 3 | 100 | 200 | 1000 | — | 3000 | 80 | 0 |
| Comparative Example 1 | 100 | 200 | 1000 | — | 2000 | 80 | 0 |
| Comparative Example 2 | 100 | 200 | 1000 | — | 2000 | 80 | 0 |
| Comparative Example 3 | 100 | 200 | 1000 | — | 3000 | 80 | 0 |
| Comparative Example 4 | 100 | 200 | 1000 | — | 3000 | OFF | 60 |
| Comparative Example 5 | 100 | 200 | 1000 | — | 3000 | OFF | 0 |
| Comparative Example 6 | 100 | 200 | 1000 | — | 2000 | OFF | 0 |
| Comparative Example 7 | 250 | 150 | 0 | 200 | 1000 | 80 | 0 |
| Comparative Example 8 | 250 | 150 | 0 | 200 | 1000 | 80 | 0 |
| Comparative Example 9 | — | — | 60 | (Ar)940 | 2000 | 80 | 0 |
| Example 4 | 100 | 200 | 5000 | — | 3000 | 80 | 0 |
| Example 5 | 100 | 200 | 1000 | — | 3000 | 80 | 0 |
| Example 6 | 100 | 200 | 1000 | — | 2500 | 80 | 0 |

| | |
|---|---|
| Film forming unit 100A | Film forming unit 100B |

| | | HDMS | O₂ | H₂ | Power | HDMS | O₂ | H₂ | Power |
|---|---|---|---|---|---|---|---|---|---|
| | Inorganic layer | [sccm] | [sccm] | [sccm] | [W] | [sccm] | [sccm] | [sccm] | [W] |
| Example 7 | SiO | 120 | 700 | 100 | 1000 | — | — | — | — |
| Example 8 | | 120 | 700 | 100 | 600 | — | — | — | — |
| Example 9 | | 120 | 700 | 1000 | 1000 | — | — | — | — |
| Comparative Example 10 | | 120 | 700 | 100 | 1500 | — | — | — | — |
| Comparative Example 11 | | 120 | 700 | 100 | 1000 | — | — | — | — |
| Comparative Example 12 | | 120 | 700 | 100 | 1000 | — | — | — | — |
| Comparative Example 13 | | 120 | 700 | 100 | 1000 | — | — | — | — |

Film forming unit 100C

| | HDMS | O₂ | H₂ | Power | Heating means | Drum |
|---|---|---|---|---|---|---|
| | [sccm] | [sccm] | [sccm] | [W] | [° C.] | [° C.] |
| Example 7 | 120 | 700 | 100 | 1500 | 80 | 0 |
| Example 8 | 120 | 700 | 100 | 1500 | 80 | 0 |
| Example 9 | 120 | 700 | 100 | 1500 | 80 | 0 |
| Comparative Example 10 | 120 | 700 | 100 | 1000 | 80 | 0 |
| Comparative Example 11 | 120 | 700 | 100 | 1000 | 80 | 0 |
| Comparative Example 12 | 120 | 700 | 100 | 1500 | OFF | 60 |
| Comparative Example 13 | 120 | 700 | 100 | 1500 | OFF | 0 |

| | | | | | | | | | | | | Sheet temperature | |
|---|---|---|---|---|---|---|---|---|---|---|---|---|---|
| | | First half | | | | | Second half | | | | | Second | |
| | Inorganic | BEMAS | O₂ | H₂ | Ar | Power | BEMAS | O₂ | H₂ | Ar | Power | First half | half |
| | layer | [sccm] | [sccm] | [sccm] | [sccm] | [W] | [sccm] | [sccm] | [sccm] | [sccm] | [W] | [° C.] | [° C.] |
| Example 10 | SiO (ALD) | 50 | 50 | 100 | 500 | 200 | 50 | 50 | 20 | 500 | 300 | 80 | 40 |

The following measurement was performed on the prepared gas barrier films. All the measurements were performed after the protective film Gb was peeled off.

[Measurement of Hydrogen Concentration]

Regarding the inorganic layer 26 of each of the prepared gas barrier films, the hydrogen concentrations of the support side 26L and the surface side 26U was measured by the RBS/HFS method using a Rutherford backscattering analyzer (HRBS-V500, manufactured by KOBELCO) as described above.

[Measurement of Infrared Absorbance Spectra of Front Surface and Back Surface of Support]

The prepared gas barrier film was cut, and the infrared absorption spectra of the front surface and the back surface of the support 22 at the cross section were measured by microscopic infrared spectroscopy using a total reflection method using an infrared microscope (IRT-5200, manufactured by JASCO Corporation). From the measured infrared absorption spectra, a peak intensity ratio A (front surface) and a peak intensity ratio B (rear surface) of “peak intensity of 3000 to 3500 cm⁻¹/peak intensity of 2700 to 3000 cm⁻¹ (O—H/C—H)” on the front surface and the rear surface of the support 22 were measured and the ratio “peak intensity ratio A/peak intensity ratio B” was calculated.

As the evaluation of the gas barrier film, the water vapor transmission rate, the surface roughness Ra of the inorganic layer 26, and the total light transmittance were measured.

[Measurement of Water Vapor Transmission Rate]

The water vapor transmission rate [g/(m²·day)] of the prepared gas barrier film was measured under the conditions of a temperature of 40° C. and a relative humidity of 90% RH by a calcium corrosion method (the method described in JP2005-283561A).

[Surface Roughness Ra of First Inorganic Layer]

The surface roughness Ra (arithmetic mean roughness Ra) of the surface of the inorganic layer 26 was measured using an atomic force microscope (AFM, manufactured by Hitachi High-Tech Science, AFM 5000) according to JIS B 0601 (2001).

[Total Light Transmittance]

The total light transmittance of the prepared gas barrier film was measured using SH-7000 manufactured by Nippon Denshoku Industries Co., Ltd. according to JIS K 7361 (1997).

The results are shown in Table 2 below.

TABLE 2

| | | | | | Infrared absorption | | | | | |
|---|---|---|---|---|---|---|---|---|---|---|
| | | Hydrogen concentration | | | intensity ratio | | | Evaluation | | |
| | | Support | Surface | | (O—H/CH) | | | Water vapor | Surface | |
| | | side | side | Concentration | Front | Rear | | transmission | roughness | Total light |
| | Inorganic | [% by | [% by | ratio | surface A | surface B | | rate | Ra | transmittance |
| | layer | atom] | atom] | U/L | [%] | [%] | A/B | [g/(m² · day)] | [nm] | [%] |
| Example 1 | SiN | 25 | 16 | 0.64 | 0.14 | 0.11 | 1.27 | 3.6 × 10⁻⁵ | 1.6 | 89.4 |
| Example 2 | | 19 | 8 | 0.42 | 0.31 | 0.12 | 2.58 | 4.2 × 10⁻⁵ | 1.3 | 88.8 |
| Example 3 | | 32 | 14 | 0.44 | 0.13 | 0.11 | 1.18 | 3.1 × 10⁻⁵ | 1.1 | 89.8 |
| Comparative | | 15 | 27 | 1.80 | 1.03 | 0.11 | 9.36 | 1.3 × 10⁻⁴ | 5.3 | 82.7 |
| Example 1 | | | | | | | | | | |
| Comparative | | 29 | 30 | 1.03 | 0.12 | 0.1 | 1.20 | 1.6 × 10⁻³ | 1.1 | 90 |
| Example 2 | | | | | | | | | | |
| Comparative | | 8 | 16 | 2.00 | 0.73 | 0.1 | 7.30 | 2.7 × 10⁻⁴ | 7.1 | 83.1 |
| Example 3 | | | | | | | | | | |
| Comparative | | 36 | 13 | 0.36 | 0.9 | 0.11 | 8.18 | 5.2 × 10⁻⁵ | 3.1 | 84.8 |
| Example 4 | | | | | | | | | | |
| Comparative | | 48 | 22 | 0.46 | 0.85 | 0.11 | 7.73 | 9.1 × 10⁻⁵ | 5.2 | 83.9 |
| Example 5 | | | | | | | | | | |
| Comparative | | 44 | 39 | 0.89 | 0.81 | 0.11 | 7.36 | 1.03 × 10⁻⁴ | 5.4 | 84.5 |
| Example 6 | | | | | | | | | | |
| Comparative | | 31 | 32 | 1.03 | 3.19 | 0.26 | 12.27 | 2.3 × 10⁻⁴ | 14.1 | 78.7 |
| Example 7 | | | | | | | | | | |
| Comparative | | 50 | 1 | 0.02 | 0.83 | 0.11 | 7.55 | 8.3 × 10⁻⁴ | 8.8 | 84.2 |
| Example 8 | | | | | | | | | | |
| Comparative | | 17 | 6 | 0.35 | 1.95 | 0.22 | 8.86 | 6.6 × 10⁻⁵ | 1.7 | 81.2 |
| Example 9 | | | | | | | | | | |
| Example 4 | | 42 | 28 | 0.67 | 0.15 | 0.11 | 1.36 | 3.7 × 10⁻⁵ | 1.5 | 89.5 |
| Example 5 | | 35 | 15 | 0.43 | 0.67 | 0.1 | 6.70 | 4.4 × 10⁻⁵ | 2.6 | 86.1 |
| Example 6 | | 25 | 21 | 0.84 | 0.13 | 0.11 | 1.18 | 4.8 × 10⁻⁵ | 1.4 | 89.6 |
| Example 7 | SiO | 17 | 11 | 0.65 | 0.13 | 0.1 | 1.30 | 8.5 × 10⁻⁵ | 1.9 | 90.7 |
| Example 8 | | 14 | 9 | 0.64 | 0.4 | 0.11 | 3.64 | 9.3 × 10⁻⁵ | 2 | 90.3 |
| Example 9 | | 38 | 13 | 0.34 | 0.12 | 0.11 | 1.09 | 7.7 × 10⁻⁵ | 1.3 | 90.8 |
| Comparative | | 11 | 18 | 1.64 | 0.84 | 0.1 | 8.40 | 9.9 × 10⁻⁴ | 6.1 | 83.8 |
| Example 10 | | | | | | | | | | |
| Comparative | | 30 | 32 | 1.07 | 0.13 | 0.11 | 1.18 | 5.6 × 10⁻³ | 0.9 | 90.5 |
| Example 11 | | | | | | | | | | |
| Comparative | | 33 | 8 | 0.24 | 0.97 | 0.11 | 8.82 | 1.2 × 10⁻⁴ | 4 | 84.9 |
| Example 12 | | | | | | | | | | |
| Comparative | | 46 | 17 | 0.37 | 0.79 | 0.11 | 7.18 | 1.6 × 10⁻⁴ | 4.6 | 84.3 |
| Example 13 | | | | | | | | | | |
| Example 10 | SiO | 21 | 14 | 0.67 | 0.23 | 0.11 | 2.09 | 4.3 × 10⁻⁵ | 1 | 90.4 |
| | (ALD) | | | | | | | | | |

Examples 1 to 6 and Comparative Examples 1 to 9 are examples in which a silicon nitride film is formed as the inorganic layer 26.

As shown in Table 2, all the gas barrier films 10 of the present invention have very high gas barrier properties such that the water vapor transmission rate is 5×10⁻⁵ g/(m²·day) or less, and in all the examples, the gas barrier films have high transparency with a total light transmittance of 85% or more. Further, it could be also confirmed that the surface roughness Ra of the inorganic layer 26 was 5 nm or less in all the gas barrier films, and the coatability of the inorganic layer 26 was good. Among them, in Examples 1 to 5 in which the concentration ratio of the surface side U to the support side L is 0.8 or less, both the gas barrier properties and the transparency are particularly good.

In contrast, in Comparative Examples 1 and 2 in which the hydrogen concentration on the surface side 26U is higher than the hydrogen concentration on the support side 26L in the inorganic layer 26, the gas barrier properties are low. Particularly, in Comparative Example 1 in which the ratio “peak intensity ratio A/peak intensity ratio B” is more than 7, the total light transmittance is 82.7%, and the transparency is also low.

Further, in Comparative Example 3, since hydrogen gas is not introduced in the film formation in the first film forming unit 100A and the hydrogen concentration on the support side 26L in the inorganic layer 26 is low, the coatability of the inorganic layer 26 is insufficient, the gas barrier properties are low, and the ratio “peak intensity ratio A/peak intensity ratio B” is more than 7 and the total light transmittance is also low.

In Comparative Example 4 in which the drum 102 is heated to 60° C. without performing heating by the heating means 112, the coating efficiency in the first film forming unit 100A is poor, the ratio “peak intensity ratio A/peak intensity ratio B” is more than 7, and the total light transmittance is low.

In Comparative Example 5 in which heating by the heating means 112 is not performed, since the coating efficiency in the first film forming unit 100A is poor, and the hydrogen concentration on the support side 26L is too high, the density on the support side 26L is insufficient, and the gas barrier properties are low. Further, the ratio “peak intensity ratio A/peak intensity ratio” is more than 7 and the total light transmittance is also low.

In Comparative Example 6 in which film formation is performed under the same conditions in the first film forming unit 100A and the third film forming unit 100C without performing heating by the heating means 112, since the hydrogen concentration on the surface side 26U is too high, the density on the surface side 26U is insufficient and the gas barrier properties are low. Further, the ratio “peak intensity ratio A/peak intensity ratio” is more than 7 and the total light transmittance is also low.

In Comparative Example 7, since hydrogen is not introduced at the time of film formation, the coatability is poor as shown in the surface roughness Ra. Further, since the hydrogen concentration on the surface side 26U is lower than the hydrogen concentration on the support side 26L, the gas barrier properties are low, the ratio “peak intensity ratio A/peak intensity ratio B” is more than 7, and the total light transmittance is low.

In Comparative Example 8, since hydrogen is not introduced at the time of film formation, the coatability was poor as shown in the surface roughness Ra. Further, since the hydrogen concentration on the support side 26L is high and the hydrogen concentration on the surface side 26U is low, the density on the support side 26L is low and the gas barrier properties are low. Further, the ratio “peak intensity ratio A/peak intensity ratio” is more than 7 and the total light transmittance is also low.

Comparative Example 9 is an example in which silicon nitride films are formed by the first film forming unit 100A and the second film forming unit 100B, vacuum ultraviolet rays are generated by the decomposition of hydrogen gas and argon gas by the third film forming unit 100C, and the hydrogen concentration is decreased by releasing hydrogen on the surface side to form the first inorganic layer. However, in this method, the alteration of the support 22 due to vacuum ultraviolet rays is large, the ratio “peak intensity ratio A/peak intensity ratio B” is more than 7, and the total light transmittance is low.

On the other hand, Examples 7 to 9 and Comparative Examples 10 to 13 are examples in which a silicon oxide film is formed as the inorganic layer 26.

As shown in Table 2, all the gas barrier films 10 of the present invention have high gas barrier properties such that the water vapor transmission rate is 1×10⁻⁴ g/(m²·day) or less, and all the examples have very high transparency with a total light transmittance of 90% or more. Further, it could be also confirmed that the surface roughness Ra of the inorganic layer 26 was all 2 nm or less, and the coatability of the inorganic layer 26 was good.

In contrast, in Comparative Examples 10 and 11 in which the hydrogen concentration on the surface side 26U is higher than the hydrogen concentration on the support side 26L in the inorganic layer 26, the gas barrier properties are low. Particularly, in Comparative Example 10 in which the ratio “peak intensity ratio A/peak intensity ratio B” is more than 7, the total light transmittance is 82.7% and the transparency is low.

Further, in Comparative Example 12 in which the drum 102 is heated to 60° C. without performing heating by the heating means 112, the coating efficiency in the first film forming unit 100A is poor, the ratio “peak intensity ratio A/peak intensity ratio B” is more than 7, and the total light transmittance is low.

In Comparative Example 13 in which heating by the heating means 112 is not performed, the coatability in the first film forming unit 100A is poor, and since the hydrogen concentration on the support side 26L is too high, the density on the support side 26L is insufficient and the gas barrier properties are low. Further, the ratio “peak intensity ratio A/peak intensity ratio” is more than 7 and the total light transmittance is also low.

In Example 9 in which a silicon oxide film is formed by an atomic layer deposition method as the inorganic layer 26, the gas barrier film also has high gas barrier properties such that the water vapor transmission rate is 5×10⁻⁵ g/(m²·day) or less, and has a very high transparency of a total light transmittance of 90% or more.

From the above results, the effect of the present invention is apparent.

### EXPLANATION OF REFERENCES

10, 12: gas barrier film
22: support
24: first organic layer
26: first inorganic layer
26L: support side (region X)
26U: surface side (region Y)
28: second organic layer
40: organic film forming apparatus
52, 92: rotating shaft
54a, 54b: pair of transport rollers
56: coating unit
58, 58a, 58b: drying unit
60: light irradiation unit
62, 108: winding shaft
64, 98: collection roll
66, 104: supply roll
72, 74, 110: roll
80: inorganic film forming apparatus
82: vacuum chamber
84: evacuation means
94a to 94c, 106a to 106c: pass roller
100A: first film forming unit
100B: second film forming unit
100C: third film forming unit
102: drum
112: heating means
114: shower electrode
116: high frequency power supply
118: gas supply means
A, B: sheet
Ga, Gb: protective film

What is claimed is:

1. A gas barrier film comprising:
a support; and
an inorganic layer which is formed on one surface side of the support and contains at least one of oxygen, nitrogen, or carbon, silicon, and hydrogen,
wherein in the support, a peak intensity ratio A of an infrared absorption spectrum at a surface on which the inorganic layer is formed and a peak intensity ratio B of an infrared absorption spectrum at a surface opposite to the surface on which the inorganic layer is formed satisfy 1≤peak intensity ratio A/peak intensity ratio B≤7,
the peak intensity ratio A and the peak intensity ratio B are expressed as a peak intensity of 3000 to 3500 cm⁻¹/a peak intensity of 2700 to 3000 cm⁻¹,
the inorganic layer includes two regions of a region Y and a region X having the same thickness as that of the region Y and arranged to be closer to the support than the region Y,
a hydrogen atom concentration L in the region X is 10% to 45% by atom, and a hydrogen atom concentration U in the region Y is 5% to 35% by atom and is lower than the hydrogen atom concentration L, and
the hydrogen atom concentration L or the hydrogen atom concentration U is expressed by the following expression,
[hydrogen atom/(silicon atom+hydrogen atom+oxygen atom+nitrogen atom+carbon atom)]×100 (Expression).

2. The gas barrier film according to claim 1,
wherein a ratio of the hydrogen atom concentration U to the hydrogen atom concentration L is 0.3 to 0.8.

3. The gas barrier film according to claim 1, further comprising:
an underlying organic layer which is an underlying layer of the inorganic layer,
wherein the gas barrier film has one or more combinations of the underlying organic layer and the inorganic layer.

4. A film forming method for, while transporting a long base material in a longitudinal direction, forming inorganic layers containing at least one of oxygen, nitrogen, or carbon, silicon, and hydrogen, on a surface of the base material under film formation conditions different from each other by at least two film forming units including a first plasma CVD unit, and a second plasma CVD unit disposed on a downstream side of the first plasma CVD unit in a transport direction, the method comprising sequentially performing the steps of:
heating the base material;
forming the inorganic layer on the base material by the first plasma CVD unit using hydrogen as a raw material gas; and
forming another inorganic layer on the base material on which the inorganic layer is formed by the second plasma CVD unit.

5. The film forming method according to claim 4,
wherein the inorganic layers are formed under different film formation conditions from each other such that a hydrogen atom concentration of the inorganic layer formed by the film forming unit on the downstream side in the transport direction out of the at least two film forming units is lower than a hydrogen atom concentration of the inorganic layer formed by the film forming unit on the upstream side in the transport direction.

6. The film forming method according to claim 4,
wherein the film formation conditions are different from each other in at least one of plasma excitation power, film formation pressure, a frequency of plasma excitation power, an amount of hydrogen to be supplied as a raw material gas, or temperature of the base material.

7. The film forming method according to claim 6,
wherein the film formation condition includes at least one selected from conditions that the plasma excitation power is higher in the film forming unit on the downstream side than in the film forming unit on the upstream side,
the film formation pressure is lower in the film forming unit on the downstream side than in the film forming unit on the upstream side,
the frequency of plasma excitation power is higher in the film forming unit on the downstream side than in the film forming unit on the upstream side,
the amount of hydrogen to be supplied as a raw material gas is smaller in the film forming unit on the downstream side than in the film forming unit on the upstream side, and
the temperature of the base material is lower in the film forming unit on the downstream side than in the film forming unit on the upstream side.

8. The film forming method according to claim 4,
wherein the inorganic layer is formed while cooling the base material.

9. A gas barrier film comprising:
a support;
an inorganic layer which is formed on one surface side of the support and contains at least one of oxygen, nitrogen, or carbon, silicon, and hydrogen; and
an underlying organic layer which is an underlying layer of the inorganic layer,
wherein the gas barrier film has one or more combinations of the underlying organic layer and the inorganic layer, and
wherein in the support, a peak intensity ratio A of an infrared absorption spectrum at a surface on which the inorganic layer is formed and a peak intensity ratio B of an infrared absorption spectrum at a surface opposite to the surface on which the inorganic layer is formed satisfy 1≤peak intensity ratio A/peak intensity ratio B≤7,
the peak intensity ratio A and the peak intensity ratio B are expressed as a peak intensity of 3000 to 3500 cm⁻¹/a peak intensity of 2700 to 3000 cm⁻¹,
the inorganic layer includes two regions of a region Y and a region X having the same thickness as that of the region Y and arranged to be closer to the support than the region Y,
a hydrogen atom concentration L in the region X is 10% to 45% by atom, and a hydrogen atom concentration U in the region Y is 5% to 35% by atom and is lower than the hydrogen atom concentration L,
a ratio of the hydrogen atom concentration U to the hydrogen atom concentration L is 0.3 to 0.8 and
the hydrogen atom concentration L or the hydrogen atom concentration U is expressed by the following expression,
[hydrogen atom/(silicon atom+hydrogen atom+oxygen atom+nitrogen atom+carbon atom)]×100 (Expression).
